(19) United States
(12) Patent Application Publication
(10) Pub. No.: US 2026/0260146 A1
(43) Pub. Date: Sep. 3, 2026

(54) SCALABLE COUPLING ARCHITECTURES AND CONTROL METHODS FOR SUPERCONDUCTING QUBITS

(71) Applicant: Atlantic Quantum Corp., Cambridge, MA (US)

(72) Inventors: Youngkyu Sung, Cambridge, MA (US); Bharath Kannan, Cambridge, MA (US); Leon Chen Ding, Cambridge, MA (US); Konstantin Nesterov, Cambridge, MA (US)

(73) Assignee: Atlantic Quantum Corp., Cambridge, MA (US)

(21) Appl. No.: 19/006,755

(22) Filed: Dec. 31, 2024

Related U.S. Application Data
(60) Provisional application No. 63/668,591, filed on Jul. 8, 2024.

(51) Int. Cl. G06N 10/40

(52) U.S. Cl. CPC G06N 10/40

(57) ABSTRACT

Techniques are described for coupling superconducting qubits, and for performing entangling operations on superconducting qubits, which simplify the control hardware for qubits while providing for high fidelity operations. Superconducting qubits may be coupled together via a tunable coupler that may be controlled to adjust the energy of one or more states of the coupler, allowing the extent to which states of the coupler couple to states of the qubits to be adjusted. For instance, the coupler may be controlled to turn the coupling between the qubits on and off. Moreover, entangling gates between the qubits may be performed by driving the coupler and/or the qubits between their different states.

### CROSS-REFERENCE TO RELATED APPLICATIONS

The present application claims the benefit under 35 U.S.C. § 119(e) of U.S. Provisional Patent Application No. 63/668,591, filed Jul. 8, 2024, titled “Scalable Coupling Architectures and Control Methods for Superconducting Qubits,” which is hereby incorporated by reference in its entirety.

### TECHNICAL FIELD

This disclosure relates to manipulating qubits in a quantum computing system, and in particular for controlling qubits to perform entangling (e.g., two-qubit) gates.

### BACKGROUND

Quantum computing platforms promise to provide solutions to many computationally intractable problems. In a quantum computing platform, information is stored in quantum bits or “qubits,” and the power of the platform generally increases with the number of qubits that can be independently and simultaneously controlled. In quantum computing platforms comprising qubits such as trapped ions or neutral atoms, directed electromagnetic waves (e.g., microwaves, optical beams) implement independent qubit manipulations, while platforms comprising qubits such as electron dots or superconducting circuits use guided RF or microwave beams.

### SUMMARY

According to some aspects, the techniques described herein relate to a system including: a first fluxonium qubit; a second fluxonium qubit; a coupling circuit coupled to each of the first fluxonium qubit and the second fluxonium qubit, the coupling circuit exhibiting at least two modes; and at least one controller configured to adjust one or more energy levels of the at least two modes of the coupling circuit to thereby increase or decrease a coupling strength between the first fluxonium qubit and the second fluxonium qubit via one or more of the at least two modes of the coupling circuit.

According to some aspects, the techniques described herein relate to a method including: controlling a flux bias of a coupling circuit, wherein the coupling circuit is coupled to a first fluxonium qubit and a second fluxonium qubit and exhibits at least two modes, wherein controlling the flux bias of the coupling circuit increases a coupling strength between the first fluxonium qubit and the second fluxonium qubit via one or more of the at least two modes of the coupling circuit; and applying at least one microwave pulse to at least one of the first fluxonium qubit, the second fluxonium qubit and the coupling circuit to perform an entangling gate between the first fluxonium qubit and the second fluxonium qubit.

The foregoing apparatus and method embodiments may be implemented with any suitable combination of aspects, features, and acts described above or in further detail below. These and other aspects, embodiments, and features of the present teachings can be more fully understood from the following description in conjunction with the accompanying drawings.

### BRIEF DESCRIPTION OF DRAWINGS

Various aspects and embodiments will be described with reference to the following figures. It should be appreciated that the figures are not necessarily drawn to scale. In the drawings, each identical or nearly identical component that is illustrated in various figures is represented by a like numeral. For purposes of clarity, not every component may be labeled in every drawing.

FIG. 1 is a schematic diagram of an example quantum computing system, according to some embodiments;

FIG. 2 is a schematic diagram of an example instrumentation system for a quantum computing system, according to some embodiments;

FIG. 3A depicts a qubit-coupler-qubit system, according to some embodiments;

FIG. 3B shows a schematic diagram of the states of the qubit-coupler-qubit system shown in FIG. 3A, according to some embodiments;

FIG. 3C-3G depict illustrative energy level diagrams of a qubit-coupler-qubit system, according to some embodiments;

FIGS. 4A-4D are schematic diagrams of example superconducting circuits, according to some embodiments;

FIG. 5A depicts a first illustrative implementation of a qubit-coupler-qubit system with a dual-mode coupler, according to some embodiments;

FIG. 5B depicts a second illustrative implementation of a qubit-coupler-qubit system with a dual-mode coupler, according to some embodiments;

FIGS. 5C-5G depict illustrative circuits that can each be used as a sub-circuit within the systems of FIGS. 5A and 5B, according to some embodiments;

FIG. 6 depicts the relationship between transition energy and coupler flux bias for three illustrative state transitions, according to some embodiments;

FIG. 7 is a schematic diagram of an example system to drive multiple qubits, according to some embodiments;

FIGS. 8A-8D are schematics of illustrative quantum computing systems in which entangling gates may be performed between qubits using a shared microwave source, according to some embodiments;

FIG. 9 is a flowchart of a method of performing an entangling gate, according to some embodiments;

FIGS. 10A-C are schematic diagrams of two-qubit gate pulse sequences to drive an example quantum computing system, according to some embodiments;

FIG. 11 is a schematic diagram of an example quantum computing system, according to some embodiments;

FIGS. 12A-B are schematic diagrams of example quantum computing systems comprising coupler interconnects between quantum processor chips, according to some embodiments;

FIGS. 12C-D are schematic diagrams of example quantum computing systems comprising coupler interconnects between quantum processor chips, according to some embodiments; and

FIG. 13 illustrates an example of a computing system environment on which aspects of the disclosure may be implemented.

### DETAILED DESCRIPTION

Qubits can be implemented in superconducting circuits that are engineered to exhibit two or more discrete quantum states at different levels of energy. Superconducting qubits typically include one or more non-linear devices, such as Josephson junctions, so that only desired transitions between quantum states can be stimulated. Superconducting circuits also have the advantage of being non-dissipative at low temperatures.

There are several different types of superconducting qubits that exhibit distinct energy states such that two of the states can be mapped to the logical quantum states |0 [symbol] and |1 [symbol] . For instance, a charge qubit exhibits states that correspond to different discrete amounts of charge in a small superconducting area, whereas a flux qubit exhibits energy states that correspond to different persistent current states around a superconducting loop.

One type of superconducting qubit is the fluxonium qubit. Fluxonium qubits offer inherent noise protection against environmental noise sources, allowing for longer coherence times compared to other superconducting qubits like the transmon. For this reason, a fluxonium qubit is considered a promising building block for low-error quantum computers. However, maintaining long coherence times for fluxonium qubits, as well as the high fidelity of logic gates, can be challenging to implement in a system comprising a large number of coupled fluxonium qubits.

The inventors have recognized and appreciated techniques for coupling fluxonium qubits using a dual-mode coupler. In particular, a dual-mode coupler may couple together two fluxonium qubits and may exhibit at least two states that have different coupling strengths with the fluxonium qubits. The dual-mode coupler may be controlled to adjust the energy levels of one or more states of the coupler, allowing the extent to which the dual-mode coupler couples to the fluxonium qubits to be adjusted. For instance, the dual-mode coupler may be controlled to turn the coupling between the fluxonium qubits on and off.

According to some embodiments, the superconducting qubits and the dual-mode coupler are implemented as superconducting circuits that exhibit different flux states. For instance, the superconducting qubits may be flux qubits, such as fluxonium qubits, and the coupler may be a superconducting circuit that includes a superconducting loop through which a magnetic flux is threaded and around which a persistent current may be generated. In this example, the energy of one or more states of the coupler may be adjusted by adjusting the flux through the coupler, which can increase or decrease an effective coupling between qubits that are coupled together via the coupler. For example, where two states are far apart in energy, the coupling between these states may be different compared with a situation in which these states have been manipulated to be much closer together in energy.

Entangling gates may be applied to the qubits by driving either or both qubits and/or the coupler between states of the qubit-qubit-coupler system. This approach has an advantage that the flux qubits may be biased to their so-called ‘sweet spot’ and this bias maintained during the entangling gate. In other approaches, a flux qubit may be driven away from the sweet spot during gates, which may compromise qubit coherence and/or reduce fidelity of the gates. By adjusting the flux bias of the coupler, but not the qubits, these challenges may be avoided.

The dual-mode coupler, also referred to herein as a “coupling circuit,” or simply a “coupler,” may allow qubits to be arranged further apart than conventional approaches because the coupler may eliminate (or at least reduce) the need for strong direct qubit-to-qubit coupling. This additional space may provide more space for wiring and/or may allow the use of some error correction codes that would not otherwise be available.

According to some embodiments, a dual-mode coupler may be driven or otherwise manipulated to control the effective coupling strength between two qubits, such as to switch coupling on and off, or to enable or disable qubit-qubit interactions (e.g., during a two-qubit gate). In some embodiments, the effective coupling strength can be controlled by adjusting the energy of a state of the coupler relative to states of the qubits, which adjusts the extent to which the qubit states may interact via the state of the coupler. In some embodiments, the frequency of a coupler mode is tuned by adjusting either the magnetic flux threading a superconducting loop (e.g., in the case of a flux-tunable coupler, such as a flux-tunable transmon, flux qubit, DC-SQUID, RF-SQUID, and fluxonium) or by adjusting a voltage applied to its gate electrodes (in the case of a voltage-tunable coupler like the gatemon and charge qubit).

According to some embodiments, entangling gates between fluxonium qubits may be performed by driving a transition from a computational state, such as states in which each of the qubits is in a state |0 [symbol] or |1 [symbol] to a non-computational state, which may include higher energy states of the qubit and/or higher energy states of the dual-mode coupler. Non-computational states are quantum states that lie outside the computational subspace, and are not generally intended to represent logical information or store long-term quantum information. However, they may be used during the execution of one or more entangling quantum gates as resources to induce two-qubit (or other entangling interactions). In some examples, a quantum state associated with the dual-mode coupler is substantially in a ground state before and after the execution of a two-qubit gate (e.g., the ground state has more than 50% of the total population of quantum states of the frequency-tunable coupler).

According to some embodiments, the dual-mode coupler is inductively and/or capacitively coupler to either or both of the qubits and may be tunable via an external magnetic field. Such dual-mode couplers can be used to mediate multi-qubit gate operations with high fidelities (e.g., approaching fidelities sufficient to enable fault-tolerant quantum computation) while still being compatible with the control methods described herein.

According to some embodiments, the dual-mode coupler capacitively couples to one or more control lines connected to an external control system comprising signal generators such as arbitrary waveform generators, DC sources, or microwave sources. These control lines, referred to as charge lines, control the offset charges on one or more nodes of qubit or dual-mode couplers. Electromagnetic signals delivered through a charge line may drive level transitions in one or more qubits to implement single or multi-qubit gates. The coupling capacitance between a charge line and a qubit or a dual-mode coupler typically ranges from a few attofarads (aF) to a few femtofarads.

According to some embodiments, the dual-mode coupler may comprise superconducting loops that are inductively coupled to one or more control lines connected to an external control system comprising signal generators such as arbitrary waveform generators, DC sources, or microwave sources. These control lines, also referred to as flux lines, control the magnetic flux threading one or more superconducting loops of a qubit and/or a dual-mode coupler. Electromagnetic signals delivered through a flux line may drive level transitions in one or more qubits to implement single or multi-qubit gates, or adjust the frequencies of relevant level transitions. In some examples, a dual-mode coupler may comprise, or may be coupled to, multiple flux lines, such as one for DC control and another for RF control, allowing for optimization of attenuation and filtering configurations based on the spectral features of the corresponding control signals. The mutual coupling inductance between a flux line and a dual-mode coupler may typically range from tens of femtohenries (fH) to tens of picohenries (pH).

In some quantum processors, such as those implementing transmon-based single-mode couplers, the qubits must be physically close to each other in space to effectively control qubit-qubit interaction, specifically to have the ability to completely turn coupling off. The coupling-off mechanism, when single-mode couplers used, can be understood as destructive interference between two coupling channels: coupler-mediated indirect coupling and direct qubit-qubit coupling, which have opposite signs. To turn off the effective coupling, balancing the stronger, coupler-mediated indirect coupling with the weaker direct coupling between the qubits is crucial. Perfect cancellation (i.e., switching off the coupling completely) is feasible only when the qubits are positioned close enough to enhance the direct coupling (e.g., to increase the capacitive coupling between qubits) to a level that can effectively counterbalance the indirect coupling.

In contrast, a dual-mode coupler as described herein exhibits at least two modes, with one mode providing positive coupling, and another mode providing negative coupling, between coupled qubits. Since direct qubit-qubit coupling is not involved, the qubits can be placed further apart. This physical spacing between qubits is advantageous for device layout because more space is created for wiring, which may be essential for scaling up the quantum processor. Furthermore, because there is no proximity requirement on the physical distance between coupled qubits, the coupler can be made long (e.g., longer than 1 mm), enabling long-range interactions between qubits. Such long-range interactions may significantly reduce gate overhead in the implementation of some quantum algorithms (i.e., fewer operations may be needed to perform computation) and may enable resource-efficient error-correction codes such as Low-Density Parity Check (LDPC) codes.

Following below are more detailed descriptions of various concepts related to, and embodiments of, techniques for coupling fluxonium qubits using a dual-mode coupler. It should be appreciated that various aspects described herein may be implemented in any of numerous ways. Examples of specific implementations are provided herein for illustrative purposes only. In addition, the various aspects described in the embodiments below may be used alone or in any combination, and are not limited to the combinations explicitly described herein.

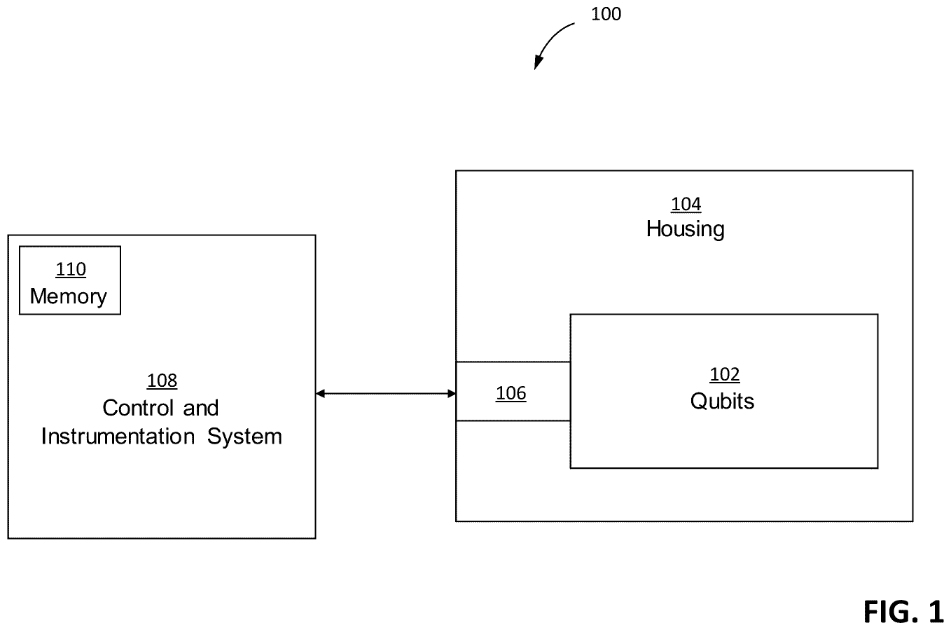

FIG. 1 shows an example quantum computing system 100 comprising qubits 102, which includes multiple qubits with at least some interconnected by a dual-mode coupler as described herein. The qubits 102 are arranged within housing 104, and send and receive signals to/from a control instrumentation system 108 via a digital signal interface 106.

As referred to herein, a “qubit” includes any multi-level quantum-mechanical system capable of being controlled within a quantum computing system, such as quantum computing system 100. The quantum states of the qubit may for instance include electronic states, polarization states, vibrational states, rotational states, or spin states. As referred to herein, a “superconducting qubit” includes any superconducting electronic circuit that may be operated as a multi-level quantum-mechanical system, such as a charge qubit (e.g., a transmon), a flux qubit (e.g., a fluxonium qubit), or a phase qubit. The term “qubit” refers to a physical implementation of a quantum system, and so for example “superconducting qubit” refers to a superconducting circuit that may be operated as a qubit.

Qubits 102 can be initialized and brought into superpositions in a controlled manner to perform quantum computation. A single-qubit gate can be used to apply a quantum operation that changes the state of a single qubit. A qubit can also be entangled with one or more other qubits such that the qubits form an entangled state. A multi-qubit gate (e.g., a two-qubit gate) can be used to apply a quantum operation that changes the states of qubits at its input, for example, to bring the qubits into a particular entangled state or to otherwise change the states of the qubits. When a qubit is measured, the wave function associated with the qubit collapses into one of the states in the superposition according to a probability that is based on the wave function. Combinations of quantum logic gates and measurement enable the realization of quantum algorithms, which can be specified using one or more collections of interconnected quantum gates (also called “quantum circuit programs” which can represent a high-level specification of operations performed on a physical device, but are generally different from the actual physical implementation of qubit circuits or other quantum device circuitry). In some systems, multiple physical qubits can be treated as representing a single logical qubit or error-corrected qubit, and quantum algorithms can be performed with respect to the logical qubits or error-corrected qubits.

In the example of FIG. 1, qubits 102 may include circuitry to connect the qubits and couplers to external signal pathways. Such circuitry may include transmission lines, resonators, filters, charge antennas, and flux antennas, for example. The qubits 102 can be operated as a quantum processor (i.e., a quantum chip) that is housed in a housing 104 (e.g., a cryogenically cooled chamber).

In the example of FIG. 1, a digital signal interface 106 is configured to receive digital control signals for performing qubit control and readout, as described in more detail below. A control and instrumentation system 108 can provide signals over the digital signal interface 106. In some implementations, the control and instrumentation system 108 can bypass the digital signal interface 106 and provide control signals directly to the qubits 102. The control and instrumentation system 108 includes a memory 110 that acts as a storage medium and may store information related to the control and instrumentation system 108 and the qubits 102. For example, the memory 110 may store a program specification (e.g., a quantum circuit program) specifying one or more algorithms comprising quantum operations.

In the example of FIG. 1, the digital signal interface 106 serves as a secondary control and instrumentation system to perform tasks that may require or benefit from real-time processing where a small signal latency between the quantum processor and the instrumentation system may be desirable (e.g., to perform real-time error decoding for fault-tolerant quantum computing). The control and instrumentation system 108 may indirectly (e.g., via the digital signal interface 106) or directly perform quantum operations on one or more of the qubits in the qubits 102 by applying coupling and transformation operations to a plurality of quantum states associated with the qubits 102, according to the program specification. For example, a radio-frequency (RF) pulse may be applied to one or more of the qubits 102 by or via the digital signal interface to alter the state of one or more of the qubits, such as producing a superposition of states in a qubit, or by driving the qubit from one state to another.

Referring to FIG. 1, the quantum processor implemented by the qubits 102 can include qubits implemented as an on-chip superconducting circuit. The qubits of the quantum processor can include a variety of types of electrical circuits. For example, the electrical circuits can include superconducting material with insulating barriers, which may be in the form of a Josephson junction. The circuits can be implemented as superconducting quantum interference devices (SQUIDs) (either direct current (DC), or radio-frequency (RF) SQUIDs), transmon qubits comprising Josephson junctions shunted by capacitive elements, and/or fluxonium qubits comprising Josephson junctions shunted by inductive and capacitive elements.

In some implementations of a quantum computing system, the individual qubit circuits of the qubits are fluxonium qubit circuits, which can be implemented as inductive loops containing a single, small Josephson junction connected to a large inductor, such as one formed by an array of multiple large Josephson junctions or formed from a particular material with kinetic inductance (e.g., granular aluminum, disordered superconducting nitrides). In fluxonium qubits, the qubit circuit is shunted by a capacitance and its properties (e.g., its operating frequency) are set by specific circuit parameters (e.g., inductance, capacitance, etc.). Some properties of fluxonium qubits also can be tuned in-situ by an external magnetic flux applied to one or more inductive loops associated with the fluxonium qubits. A fluxonium qubit circuit can have exceptionally long coherence times compared to the typical gate times for superconducting qubits, especially when operated at low frequencies. In some examples, operation at low frequencies (e.g., frequencies around or below 1 GHz), also referred to as baseband control, can be used to facilitate high-fidelity single- and multi-qubit gate operations, which can simplify the quantum system by removing high-frequency signal generators and cables. Operation at high frequencies (e.g., frequencies around or above 1 GHz) is referred to as microwave control.

The superconducting phase φᵢ a node i in a superconducting circuit is the phase of the collective quantum wavefunction of the Cooper pairs at that node. It is a macroscopic quantum variable that encapsulates the quantum mechanical properties of the superconducting state. The Hamiltonian of a superconducting circuit can be described in terms of superconducting phases at each node, superconducting phase differences between nodes, or the sum of superconducting phases of nodes. For example, a transmon superconducting qubit, formed by a Josephson junction with a Josephson energy E_{J} shunted by a capacitor with capacitance C, can be described by the following Hamiltonian:

$$H = \frac{C}{2} {( \frac{d \hat{φ}}{dt} )}^{2} - {E}_{J} cos \hat{φ}$$

where \hat{φ} is a quantum operator describing the superconducting phase difference across the Josephson junction. In this case, the transmon qubit quantum state, or mode as defined below, is associated with the superconducting phase difference between the two nodes, which are connected via a Josephson junction shunted by a capacitor.

A fluxonium qubit circuit comprises a Josephson junction with the Josephson energy E_{J} shunted by a capacitance with charging energy E_{C}, and an inductance with inductive energy E_{L}. The Hamiltonian H of a fluxonium qubit circuit can be written as

$$\frac{H}{h} = 4 {E}_{C} {\hat{n}}^{2} - {E}_{J} cos \hat{φ} + \frac{1}{2} {{E}_{L} ( \hat{φ} + {φ}_{e x t} )}^{2}$$

Here, h is the Planck constant and φₑₓₜ=2πΦₑₓₜ/Φ₀ is the reduced magnetic flux threading the superconducting loop, which is interrupted by the Josephson junction and the inductor. The Cooper pair number operator \hat{n} is associated with the number of Cooper electron pairs that have tunneled across the Josephson junction, and the superconducting phase operator \hat{φ} is associated with phase difference across the Josephson junction. In some implementations of the fluxonium qubit circuit, E_{J} ranges from 1 GHz to 10 GHz, E_{C} ranges from 0.1 GHz to 2 GHz and E_{L} ranges from 0.1 GHz to 2 GHz to ensure that the operation frequency (which is associated with the energy difference between the ground state |0> and the first excited state |1>) is around or below 1 GHz.

In the example of FIG. 1, the control and instrumentation system 108 and the digital signal interface 106 is configured for signal generation and data acquisition. Operating a quantum processor (e.g., the qubits 102) may be performed by using control electronics to generate the signals that control and probe the quantum processor, which can comprise elements such as qubits, couplers, and resonators. The control and instrumentation system 108 may include waveform generators that can generate low frequency signals (e.g., <1 GHz) to provide baseband control. Such waveform generators may be used to directly drive the qubits.

In some embodiments, the qubits 102 are flux qubits and the control and instrumentation system 108 and the digital signal interface 106 is configured to control the magnitude of a magnetic flux threaded through a flux qubit (also referred to herein as the magnitude of the flux bias of the flux qubit). In some embodiments, the qubits 102 are flux qubits, and the control and instrumentation system 108 and the digital signal interface 106 are configured to independently control a plurality of magnetic flux biases that are threaded through respective different superconducting loops within the flux qubits. In some embodiments, control of an external magnetic flux comprises providing a baseline DC current signal that is fixed, in addition to providing a time-dependent current signal that modulates the baseline DC current signal. For instance, an antenna may be mutually inductively coupled to a superconducting loop of the flux qubit, and a current signal may be provided to this antenna to adjust the magnetic flux threaded through the superconducting loop of the flux qubit.

According to some embodiments, controlling the flux bias of a flux qubit 102 by the control and instrumentation system 108 and the digital signal interface 106 comprises directing a flux bias signal (e.g., a current signal) along a flux bias line that is inductively coupled to a superconducting loop of the flux qubit (e.g., inductively coupled via an antenna).

In some embodiments, the control and instrumentation system 108 and the digital signal interface 106 may include digital and analog components, in which the analog components are configured to generate an analog flux bias signal based on digital data supplied by the digital components. Generating an analog flux bias signal in this way may include generating a digital signal and converting the digital signal to an analog signal (e.g., via a digital to analog converter (DAC)), and/or may comprise generating an analog flux bias signal based on one or more digital values.

The control and instrumentation system 108 may include microwave sources that generate high-frequency signals (e.g., >1 GHz) to provide microwave control. Such microwave sources may be used to directly drive the qubits or couplers or mixed with baseband waveform generators to shape the microwave pulses. The control and instrumentation system 108 may also include high-frequency sources (5-10 GHz) to generate readout signals at the resonator frequencies or pump tones for parametric amplifiers. In addition, direct current (DC) sources may be used to statically flux bias the quantum circuit elements.

In some embodiments, the control and instrumentation system 108 is configured to direct microwave signals (e.g., microwave pulses) to a qubit 102 (and in some cases to multiple of qubits 102) to drive a level transition of the qubit. The control and instrumentation system 108 may be configured to drive such a transition by applying a microwave pulse that stimulates Rabi oscillations between two states having a transition frequency that corresponds to the frequency of the microwave pulse (or which is detuned therefrom). For example, the control and instrumentation system 108 may be configured to direct a microwave pulse through one or more drive lines (also called charge lines) that are capacitively or inductively coupled to the qubit, and which drive a transition between states. The control and instrumentation system 108 may also be configured to direct a microwave pulse through one or more drive lines that are capacitively or inductively coupled to a coupler that couples together two qubits, as described further below.

In some embodiments, the control and instrumentation system 108 includes a microwave source that produces a microwave signal at a single frequency. As described above, one of the advantages of the techniques described herein may be to reduce the complexity of the microwave electronics needed to control the states of superconducting qubits. One way in which this complexity may be reduced is to utilize a microwave source at a single frequency for driving entangling (e.g., two-qubit) gates on multiple qubits (e.g., multiple qubit pairs). It will be appreciated that, in practice, the microwave signal may not necessarily have a bandwidth that is precisely zero, though such a signal may nonetheless be considered a single-frequency microwave signal so long as the bandwidth is sufficiently small.

According to some embodiments, the digital signal interface 106 may include digital and analog components, wherein the analog components generate an analog microwave signal based on digital data supplied by the control and instrumentation system 108. Generating an analog microwave signal in this way may include generating a digital signal and converting the digital signal to an analog signal (e.g., via a digital to analog converter (DAC)), and/or may comprise generating an analog microwave signal based on one or more digital values.

In some embodiments, the digital signal interface 106 comprises one or more digital devices, which may include a general purpose computing device and/or digital logic devices such as ASICs or FPGAs, and/or may include low temperature digital logic devices such as one or more cryo-CMOS, adiabatic quantum flux parametron (AQFP), single-flux quantum (SFQ), and/or quantum flux parametron (QFP) devices. In some embodiments, the digital signal interface 106 comprises one or more mixers implemented in low temperature digital logic, such as AQFP, which are configured to mix an oscillator current and a shaping current to produce a microwave pulse, which is switched on and off based on one or more digital current inputs. The generated microwave pulse(s) may be directed through one or more drives lines to one or more of the qubits 102.

In some embodiments, the digital signal interface 106 comprises one or more superconducting digital logic circuits. In order to acquire data from the quantum processor, digitizers may convert the analog readout pulses to digital data. The data may then be demodulated with field-programmable gate arrays (FPGAs) and/or in software. The control and instrumentation system 108 may include a controller box containing FPGAs that interfaces to a conventional computer to execute measurement and calibration programs and handle user inputs. Some or all of these control and instrumentation capabilities can also be implemented within the digital signal interface 106, either in part or as a whole, to reduce overall signal latency in the system.

Additional sub-systems of the quantum computing system can be connected to the quantum processor and/or to one another.

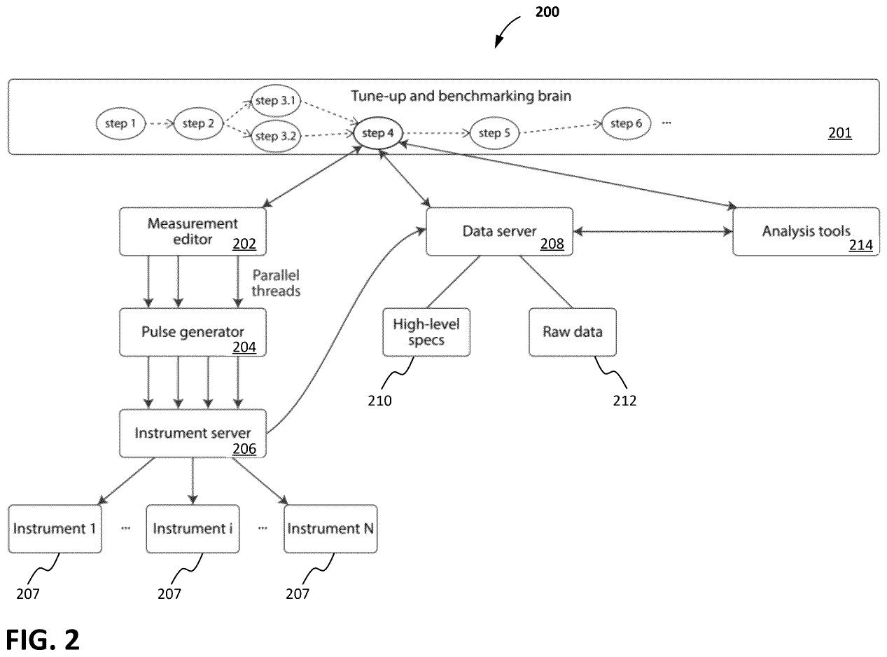

FIG. 2 shows an example system 200 comprising firmware infrastructure for agile instrument control and data handling, enabling automated tune-up and benchmarking. In this example, a tune-up and benchmarking manager 201 performs procedures with the use of various interacting modules. The modules can be implemented using firmware executing on computing circuitry integrated with a quantum system, or software executing on one or more processors of a separate classical computing system. Any given step of a procedure may involve one or more of the modules. For example, a measurement editor module 202 can use parallel threads to interact with a pulse generator module 204. The pulse generator module 204 can use parallel threads to interact with an instrument server module 206, which can manage a connection of N instrument procedures 207 and communicate with a data server module 208, which may access high-level specifications 210 (e.g., specifications of quantum circuits), and raw data 212. An analysis tools module 214 can also communicate with the tune-up and benchmarking manager 201 and the data server module 208.

Some of the instrumentation, system design, or other techniques described above, can be implemented using a program comprising instructions for execution on a classical computing device or module including one or more processors or other circuitry for executing the instructions. For example, the instructions may execute procedures of software or firmware that runs on one or more programmed or programmable computing devices or modules including at least one processor and at least one data storage system (e.g., including volatile and non-volatile memory, and/or storage media). The programs may be provided on a computer-readable storage medium, readable by a general or special purpose programmable computer, and/or delivered over a communication medium such as network to a computer where it is executed. Each such program may be stored on or downloaded to a storage medium (e.g., solid state memory or media, or magnetic or optical media) readable by a computing device, for configuring and operating the device when the storage medium is read by the device to perform the procedures of the program.

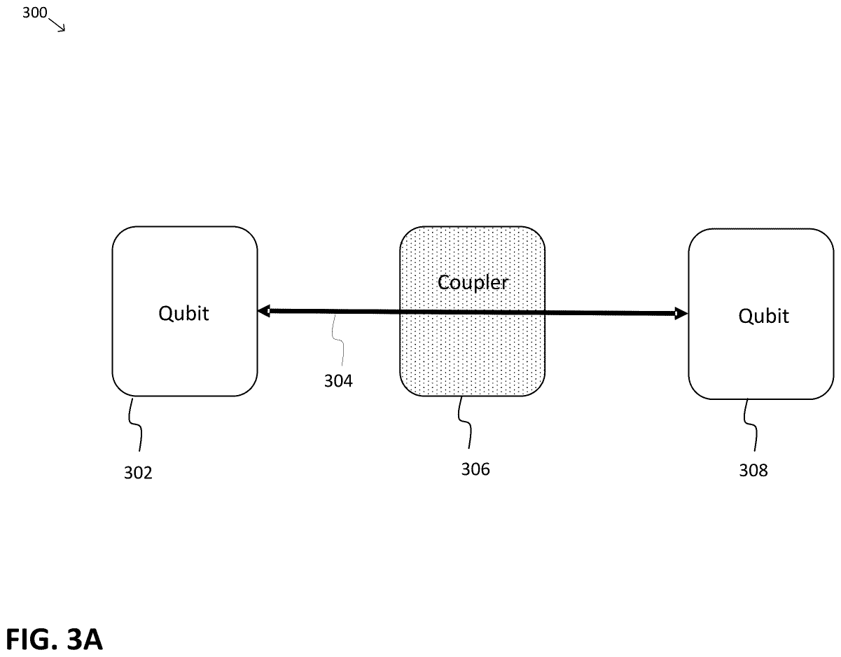

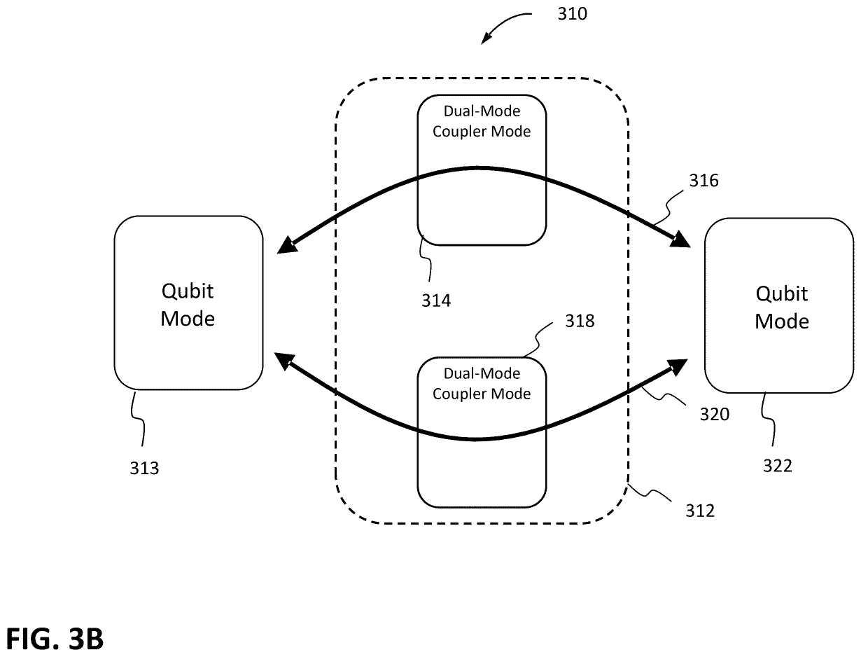

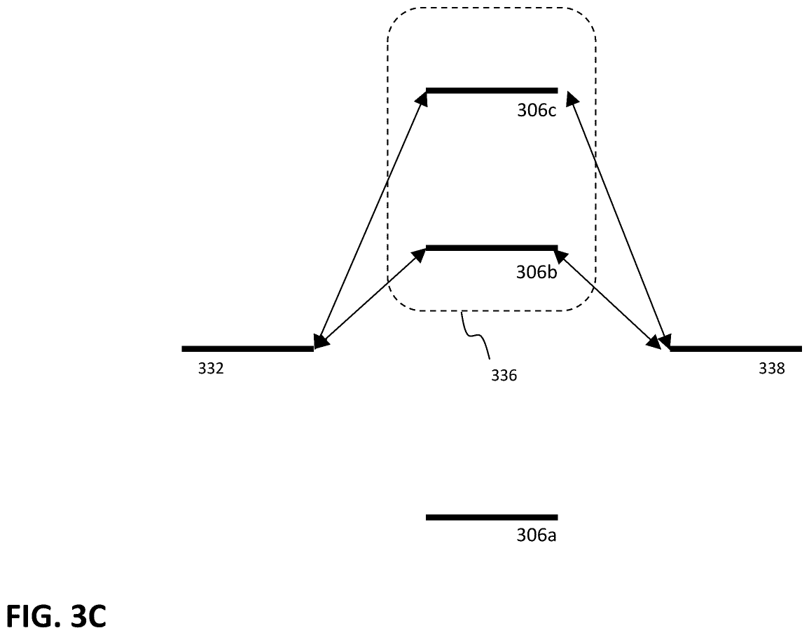

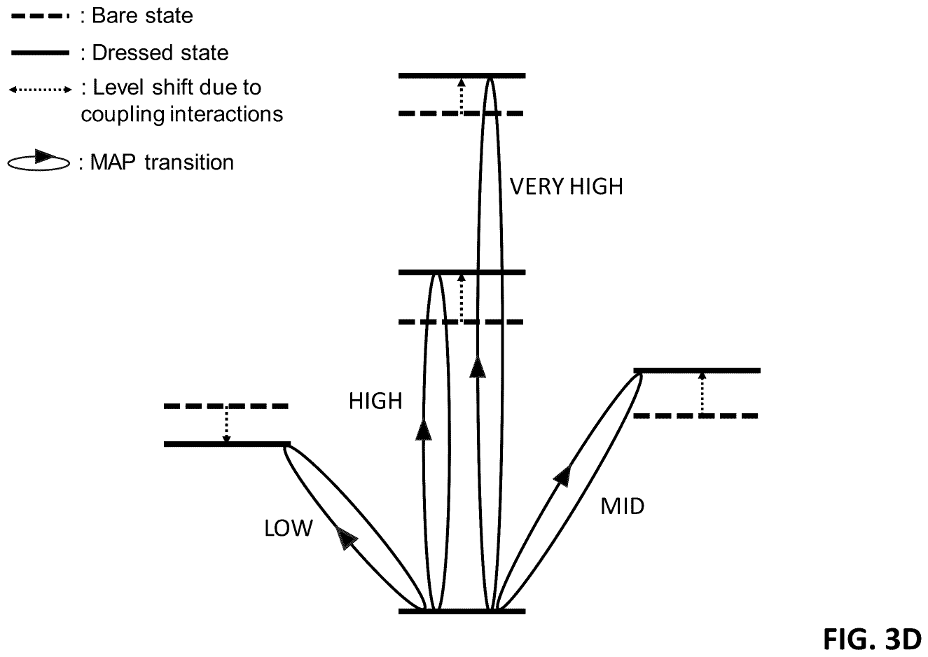

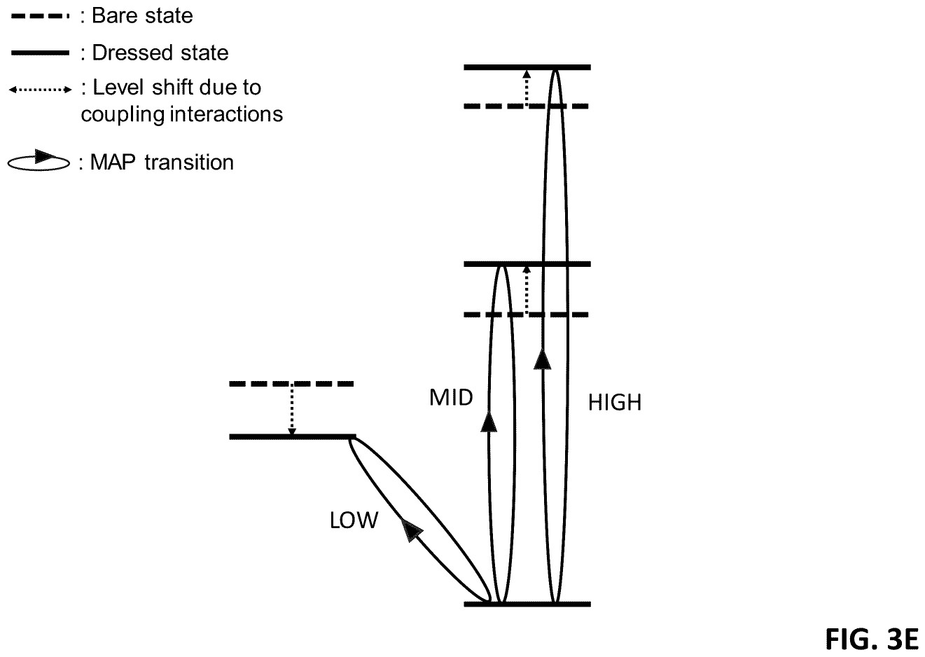

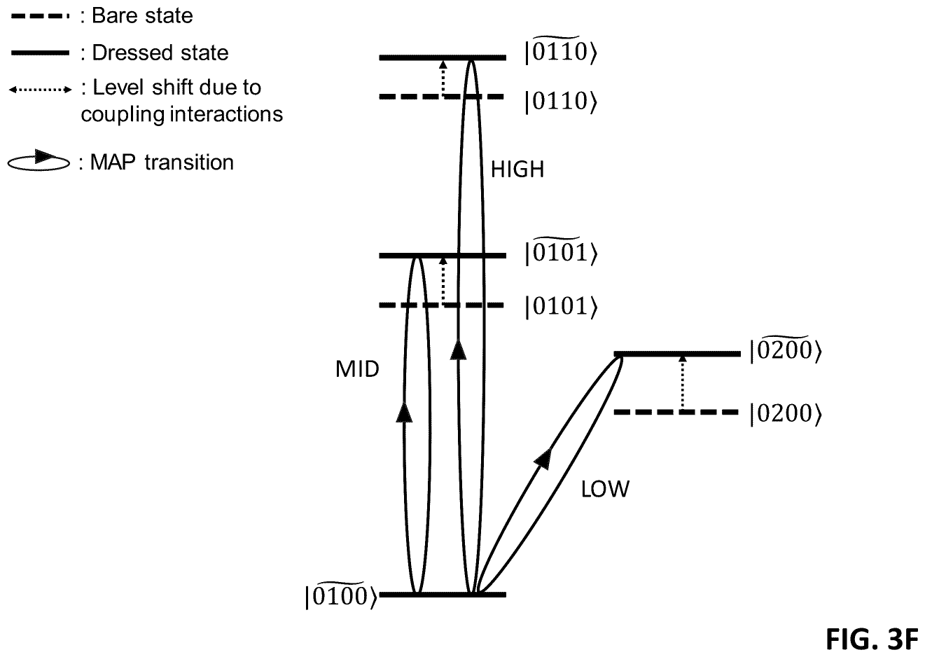

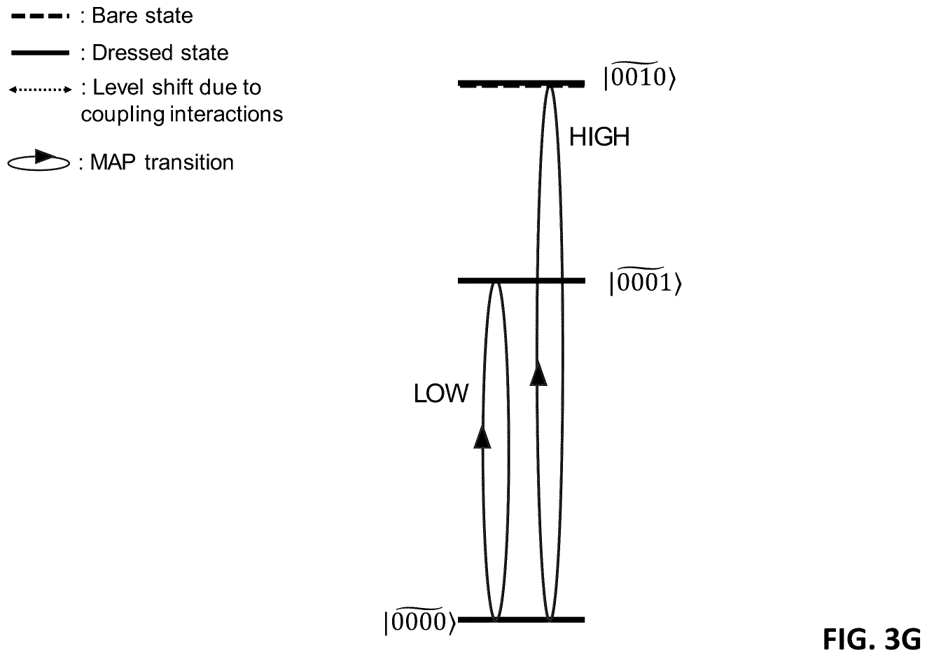

FIG. 3A depicts an example system 300 containing qubit 302 (e.g., a superconducting qubit) that is coupled to another qubit 308 (e.g., a superconducting qubit) through a coupler 306. Arrow 304 represents the coupling of the quantum states of the qubit 302 and the qubit 308, according to an effective coupling strength.

The effective coupling strength is associated with a rate at which quantum state population between a first quantum state (e.g., of a first superconducting circuit) and a second quantum state (e.g., of a second superconducting circuit) are transferred. The quantum state population of a quantum state is equal to the square of the absolute amplitude of the quantum state's wave function and characterizes the probability that measurement of a qubit associated with the quantum state will yield the quantum state. Thus, a larger quantum state population of a given quantum state translates to a larger probability of measuring a qubit to be in the given quantum state. In some examples, the wave functions of different quantum states can interfere (e.g., destructively or constructively) with one another, and thus alter the quantum state population of the quantum states. In some quantum operations that involve three or more quantum states, quantum state population may be transferred between a first quantum state and a third quantum state, via a second quantum state, without placing substantial quantum state population in the second quantum state during the transfer. The effective coupling strength may depend at least in part on an inherent coupling strength that can depend on the superconducting circuits and the capacitances or inductances that connect them, for example. The effective coupling strength may also depend on two or more other effective coupling strengths (e.g., a first effective coupling strength, between a first and a second qubit, and a second effective coupling strength, between the second and a third qubit, can result in a third effective coupling strength, between the first and third qubits). In superconducting circuits, the flow of electric charge can be quantized and thus associated with quantum states each with respective quantum state populations. Since the flow of the electric charge results in a magnetic flux, the magnetic flux of a superconducting circuit may also be quantized and associated with quantum states.

According to some embodiments, coupler 306 comprises one or more modes through which the qubits 302 and 308 can interact. In a quantum system, a mode refers to a distinct quantum state or a set of quantum states that the system can occupy. In some quantum systems, modes can be represented as a set of eigenstates of the Hamiltonian of the quantum system. Each mode is associated with a specific quantum operator or variable, which is associated with a physical quantity, such as charge across a capacitor, magnetic flux in an inductor, or phase difference across a Josephson junction. For example, the mode of a resonator formed by a linear inductor L and a capacitor C, can be defined as the eigenstates of the following Hamiltonian:

$$\hat{H} = \frac{{\hat{N}}^{2}}{2 C} + \frac{{\hat{Φ}}^{2}}{2 L} Φ$$

where \hat{N} is a quantum operator corresponding charge difference across the capacitor and \hat{Φ} is a quantum operator corresponding magnetic flux in the inductor.

A computational subspace refers to the subset of the entire Hilbert space of a quantum system that is used for performing quantum computations. It is the space spanned by the computational basis states, which are the states that represent logical information, i.e. bits, in a quantum system. For instance, when qubit and coupler modes exist in the system, the computational subspace includes only those states where the qubits are in their ground state or first excited state (|0 [symbol] or |1 [symbol] ) and the couplers are in their ground state (|0 [symbol] ).

A system of components including qubits and/or couplers can be represented in terms of the underlying quantum states of the components. For instance, the state of a system comprising two qubits connected by a coupler having two modes can be represented as |QB1 QB2 CPLR1 CPLR2 [symbol] , where QB1, QB2 are the states of qubit mode 1 and qubit mode 2 and CPLR1, CPLR2 are the states of the coupler mode 1 and coupler mode 2 that provides coupling between the qubits. In the case of the example of FIG. 3B, for instance, the state of qubit mode 313 may be represented as QB1, the state of qubit mode 322 may be represented as QB2, the state of the coupler mode of the dual-mode coupler 312 may be represented as CPLR1 and the state of the coupler mode 314 may be represented as CPLR2. For example, where each of the qubit 302, qubit 308 and dual-mode coupler 306 exhibit energy states that are treated as basis states |0 [symbol] , |1 [symbol] or |2 [symbol] , the state of the system 300 when the qubit 302 is in state |1 [symbol] , the qubit 308 is in state |0 [symbol] , the first mode of the coupler 306 is in state |0 [symbol] , and the second mode of the coupler 306 is in state |1 [symbol] may be written as |1001 [symbol] .

One of the exemplary embodiments described herein includes two fluxonium qubits and a dual-mode coupler that is capacitively coupled to the fluxonium qubits, wherein the dual-mode coupler mediates the interaction between the coupled fluxonium qubits. Such an architecture is referred to as a Fluxonium-Dual-mode Coupler-Fluxonium (FDF) arrangement. FIG. 3B shows a schematic diagram of a system 310 that includes a dual-mode coupler that couples together two qubits.

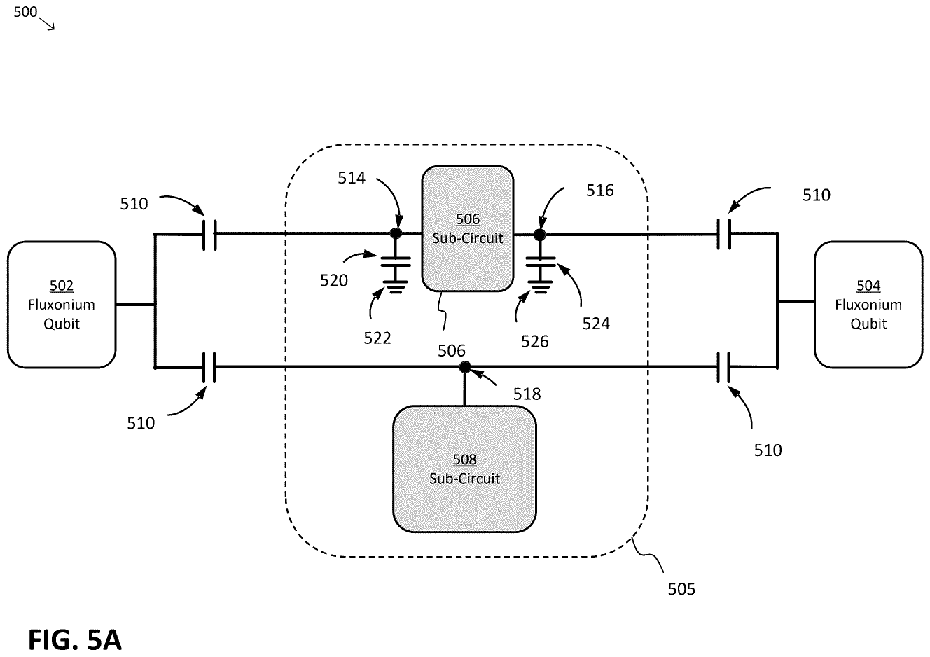

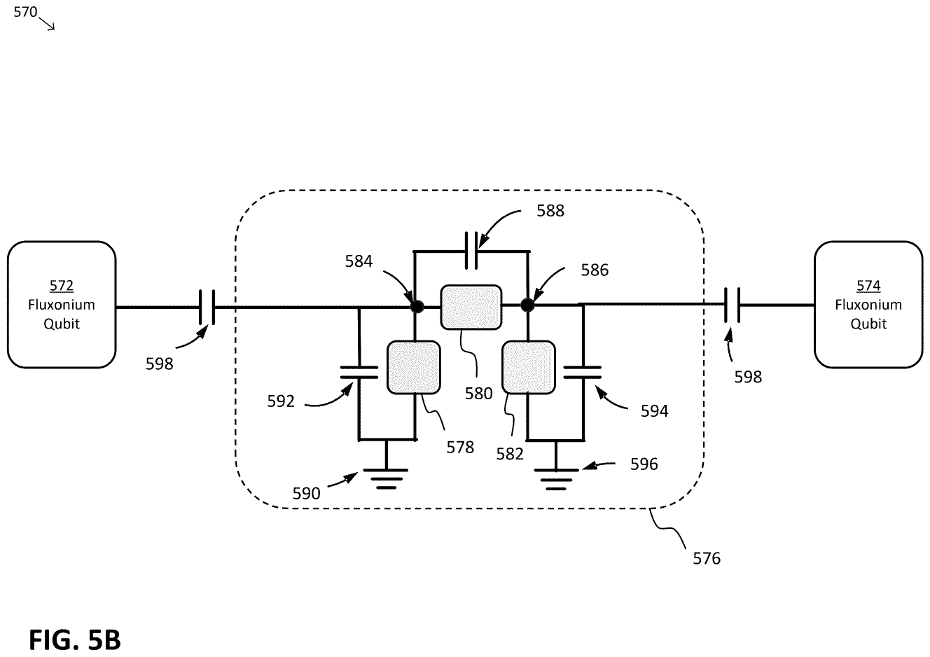

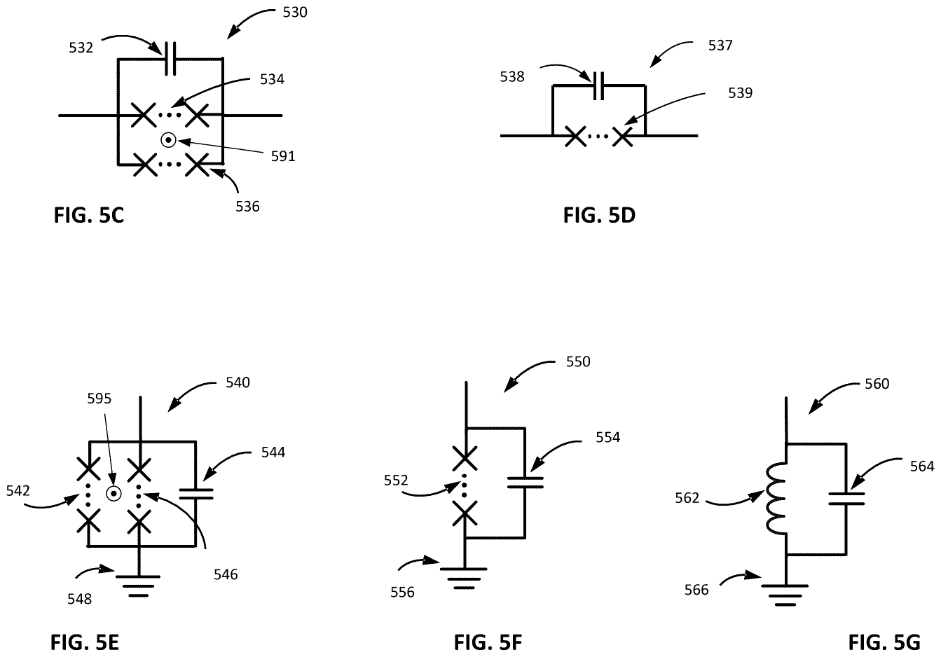

In the example of FIG. 3B, dual-mode coupler 312 comprises two modes 314 and 318, with mode 314 providing positive effective coupling 316 and the other mode 318 providing negative effective coupling 320 between qubit modes 313 and 322. The coupler mode that provides positive effective coupling is referred to as the plus mode, and the coupler mode that provides negative effective coupling is referred to as the minus mode. Circuits that can provide dual-mode coupling capabilities are illustrated in FIGS. 5A to 5G.

FIG. 3C shows a schematic diagram of the qubit-coupler-qubit system shown in FIG. 3B, according to some embodiments. In the example of FIG. 3C, two qubit modes 332 and 338 interact through dual modes of a coupler. Three states 306a, 306b and 306c of the qubit-coupler-qubit system are depicted, which differ in the state of the coupler; in each, the qubits are in their |1 [symbol] states. The two qubit modes interact through the two modes of the dual-mode coupler 336. Specifically, QB1 and QB2's higher excited states—the |2100 [symbol] and |1200 [symbol] states—can interact through two coupler-excited states—the |1110 [symbol] and |1101 [symbol] states (306b and 306c, respectively). In some embodiments, the state|1110 [symbol] provides positive effective qubit-qubit coupling, and |1101 [symbol] provides negative effective qubit-qubit coupling. In some embodiments, the state|1101 [symbol] provides positive effective qubit-qubit coupling, and |1110 [symbol] provides negative effective qubit-qubit coupling.

By controlling the coupler to tune the energies of either |1110 [symbol] and |1101 [symbol] , the effective coupling strength between |2100 [symbol] and |1200 [symbol] can be adjusted. For example, if |1110 [symbol] is brought closer to |2100 [symbol] and |1200 [symbol] , and the effective qubit-qubit interaction through |1110 [symbol] becomes stronger (coupling ON operation). On the other hand, if |1110 [symbol] is brought further from |2100 [symbol] and |1200 [symbol] , the effective qubit-qubit interaction strength through |1110 [symbol] decreases. If the effective coupling strengths through |1110 [symbol] and |1101 [symbol] are equal, but have opposite signs, they cancel each other and the interaction between |2100 [symbol] and |1200 [symbol] can be negligibly small (coupling OFF operation). According to some embodiments, turning on the qubit-qubit coupling may comprise controlling the coupler to tune the energies of the |1110 [symbol] and |1101 [symbol] states so that either |1110 [symbol] or |1101 [symbol] is resonant with |2100 [symbol] and |1200 [symbol] , and the other of |1110 [symbol] or |1101 [symbol] is not-resonant with |2100 [symbol] and |1200 [symbol] , to avoid the opposite signs of the coupling strengths cancelling each other out.

Prior to performing an entangling gate, the qubits 302 and 308, and the coupler 306, can be arranged in a state referred to herein as an idle operating regime. An idle operating regime refers to the state when the qubits are not undergoing any entangling gate operations. During this operating regime, the flux biases of fluxonium qubits may be set to half-integer magnetic flux quantum values, specifically

$${Φ}_{e x t} = ( \frac{2 n + 1}{2} ) {Φ}_{0} ,$$

where n is an integer and

$${Φ}_{0} = \frac{h}{2 e} ,$$

where h is Planck's constant and e is the charge of an electron. This choice of flux bias allows the fluxonium qubit to exhibit long coherence times due to its operation frequency being insensitive (in first-order) to external magnetic flux. Additionally, during the idle operating regime, a coupler that mediates the interactions between the qubits may be biased to the point where the net coupling between the qubits represented by arrow 304 is suppressed or turned off, allowing for isolation between the qubits.

Subsequently, the coupler 306 may be biased so that the coupling between the qubits 302 and 308 is active or turned on, thereby allowing entangling gates to be performed between the qubits.

In some cases, the states of the qubits and the coupler may interact with one another (and possibly other components within the same system), leading to changes in the energy level of one or more of these states. The intrinsic quantum states of a system without considering any interactions between the system components may be referred to as “bare” states, whereas the quantum states of the system that take into account any interaction of the qubits and couplers may be referred to as “dressed” states. In other words, bare states describe the state of a qubit or coupler that is isolated from other components. On the other hand, dressed states describe the state of the system including any interaction of the qubits and couplers. These dressed states incorporate the shifts and modifications in the energy level of states, and reflect the properties of the qubit and coupler states resulting from such interactions. Herein, the bare state representation and dressed state representation are distinguished by putting tilde on the state, e.g., |1100 [symbol] vs [symbol] , where |1100 [symbol] refers to the bare state and | [symbol] refers to the dressed state.

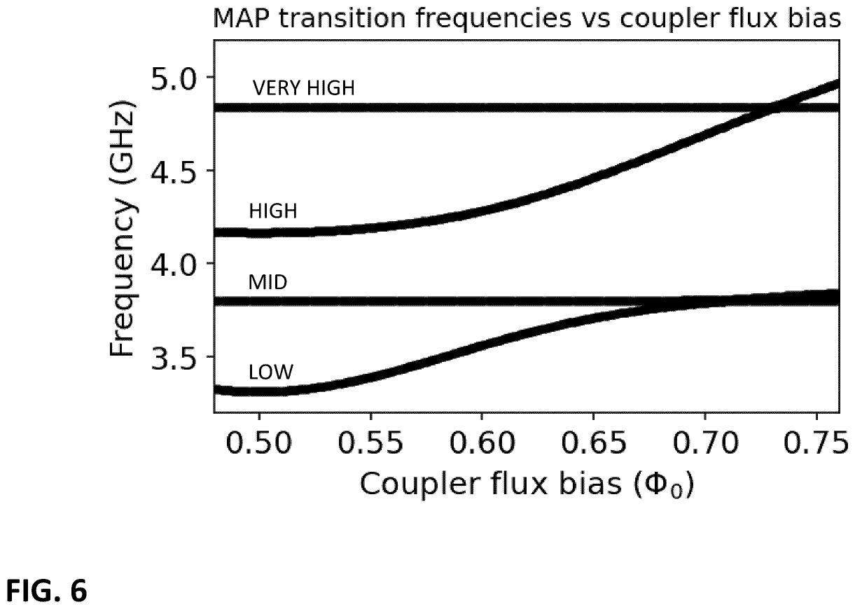

FIGS. 3D-3G depict illustrative energy level diagrams of the qubit-coupler-qubit system 300 shown in FIG. 3A, according to some embodiments. Due to the coupling between the qubits and the coupler, for example through capacitive interactions between the qubit and coupling circuits, the qubit states and coupler state are hybridized. This hybridization results in level repulsion, or energy level shifts, resulting in the dressed states as illustrated in FIGS. 3D-3G. In system 300, entangling gates (e.g., the conditional phase (CPHASE) gate) may be performed on the qubits by driving state transitions from the computational states | [symbol] , | [symbol] , | [symbol] and | [symbol] ; the relevant transitions for these four cases are shown in FIGS. 3D, 3E, 3F and 3G, respectively. The state transitions can be driven by sending microwave pulses through the flux bias lines or charge lines of qubits or/and couplers, as described above, and may be referred to herein as microwave activated phase (MAP) transitions. The labels of “LOW,” “MID,” “HIGH” and “VERY HIGH” in FIGS. 3D-3G correspond to the different transition energies shown in FIG. 6, which illustrates the frequency tunability of the MAP state transitions. In particular, FIG. 6 shows how the transition frequencies of these illustrative state transitions can be adjusted by adjusting the flux bias through the coupler. For example, the “LOW” state transition frequency can be varied between 3.3 GHz to 3.8 GHz by adjusting the coupler flux between 0.5Φ₀ and 0.7Φ₀.

In each of the cases shown in FIGS. 3D-3G, entangling gates may be performed by driving a particular one of the twelve transitions. Because of the depicted level repulsion, the transition frequencies of these transitions may be different, allowing only particular transitions to be driven, which therefore changes the state of one or both qubits in a manner that is dependent on their initial state. In each of FIGS. 3D-3G, the energies of the dressed and undressed states are shown as illustrative examples, and are not intended to limit any embodiments to having particular energies for any states, or any particular relative differences between the dressed and undressed states.

FIG. 6 depicts how illustrative transition frequencies of MAP transitions can be adjusted by adjusting the flux bias threaded through the coupler, according to some embodiments. For example, in the example of FIG. 6, the “LOW”, “MID”, “HIGH,” and “VERY HIGH” MAP state frequencies can be varied by adjusting the coupler flux between 0.5Φ₀ and 0.7Φ₀. The “LOW”, “MID”, and “HIGH” MAP transition frequencies may, for instance, correspond to the transitions | [symbol] to | [symbol] , | [symbol] to [symbol] and | [symbol] to | [symbol] , respectively. As described above, when the coupler's excited states | [symbol] and | [symbol] are far detuned away from the qubits' higher excited states | [symbol] and | [symbol] , and/or the states | [symbol] and | [symbol] are adjusted (e.g., driven) to be resonant with one another, the effective interaction strength between the | [symbol] and | [symbol] states is suppressed, effectively turning off coupling between these states. Consequently, driving MAP transitions at this bias point results in little or no entangling operation. To activate entangling operations, one of the | [symbol] and | [symbol] states is brought closer to the | [symbol] and | [symbol] states, while the other one of the | [symbol] and | [symbol] states is non-resonant with the | [symbol] and | [symbol] states (“Coupling-on point”). As described above in relation to FIG. 3C, this allows the | [symbol] and | [symbol] states, and the | [symbol] and | [symbol] states, to be strongly hybridized with sufficient level repulsion. This also allows the states to be selectively driven from | [symbol] to | [symbol] , | [symbol] , | [symbol] or | [symbol] without exciting other computational states: | [symbol] , | [symbol] , and | [symbol] . Similarly, selective driving is possible from | [symbol] to | [symbol] , | [symbol] or | [symbol] , from | [symbol] to | [symbol] , | [symbol] or [symbol] , and from | [symbol] to | [symbol] , | [symbol] . Importantly, the frequencies of these MAP transitions are tunable by adjusting the coupler frequency. This allows the MAP transition frequencies of multiple qubit pairs to be aligned to a single value, even if device parameters, such as the Josephson energy E_{J} of a Josephson junction in a qubit and/or coupler, deviate from the target due to fabrication variations. By achieving this frequency alignment, CPhase gates can be implemented on any of multiple qubit pairs using a single shared microwave tone. When this shared microwave tone is applied, the activation or deactivation of two-qubit gates is controlled through baseband coupler flux pulses.

Entangling gates that may be performed in this manner include a controlled phase (CPhase) gate. The CPhase gate is a type of two-qubit gate that applies a phase shift on the state of one of the qubits depending on the state of the other qubit. This conditional phase shift can be implemented by driving the transition from a computational state, such as | [symbol] , to a non-computational state, such as | [symbol] , | [symbol] , | [symbol] or | [symbol] . Non-computational states are quantum states that lie outside the computational subspace and are not treated as states that are intended to represent logical information or store long-term quantum information. However, they may be used during the execution of one or more quantum gates as resources to induce two-qubit interaction. The controlled-Z (CZ) gate is a specific type of the CPhase gate that applies a conditional phase shift of 180 degrees.

Another example entangling gate that may be performed by driving selected transitions as shown in FIGS. 3D-3G is the controlled-not (CNOT) gate. A CNOT gate is a two-qubit gate that applies an X gate on one of the qubits (the target qubit) depending on the state of the other qubit (the control qubit). In some examples, the CNOT gate can be implemented by combining the CZ gate with Hadamard gates, which are a type of single-qubit gate. For example, a CNOT gate may be applied between a control qubit and a target qubit by applying a Hadamard gate to the target qubit, applying a CZ gate (where either the control qubit or the target qubit may act as the CZ control qubit), and applying another Hadamard gate to the target qubit.

According to some embodiments, when performing an entangling gate, flux and microwave pulses applied to the system can result in unwanted single-qubit operations, such as X, Y, or Z rotations, or a combination of these rotations, on either or both qubits (or other qubits in the system). Undesired operations can be reversed by applying single-qubit gates before, during, or after the entangling gate process. These single-qubit operations can be performed virtually by adjusting the phases of the microwave pulses applied to the system without adding new pulses. In some cases, undesired Z operations can be echoed out by applying pi pulses (e.g., X(π) or Y(π)) to the qubits between the entangling gate processes. Alternatively, these same undesired single-qubit operations can be utilized to implement a different type of two-qubit gate. For instance, by combining the undesired operations from the CZ gate and extra single-qubit gates before, during, or after the two-qubit gate process, the CNOT gate can be implemented.

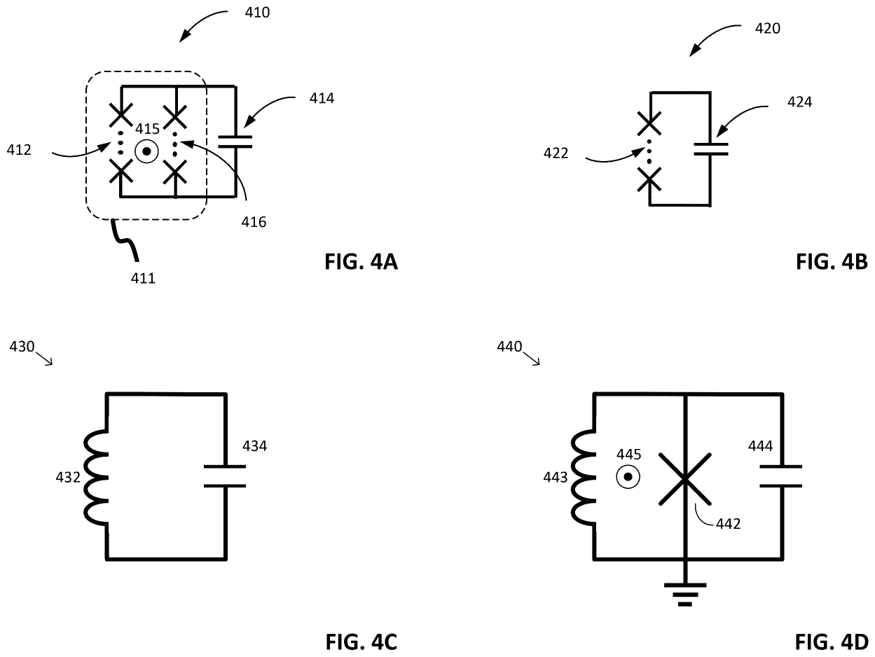

FIGS. 4A-4D depict example superconducting circuits, according to some embodiments. Each of the illustrated superconducting circuits may be operated as superconducting qubits, and used, for example, as qubits 102, 302, or 308 described above.

FIG. 4A depicts an illustrative flux qubit 410 comprising a superconducting loop 411, with its top and bottom nodes connected via a shunt capacitor 414. The shunt capacitor 414 is not part of the loop 411. In this example, the shunt capacitor 414 defines left and right sides of the loop 411. Single or multiple Josephson junctions 412 are included on the left side of the loop 411, and single or multiple Josephson junctions 416 are included on the right side of the loop 411. A Josephson junction is represented by a symbol shaped like an “X” and the two X symbols with the ellipsis dots between them here represent any number of Josephson junctions, including the case of a single Josephson junction. Thus, the loop 411 comprises a portion of a circuit that includes two or more Josephson junctions connected in series over a closed path without any capacitors in the closed path. A fluxonium qubit can be seen as an example of generalized flux qubit where its superconducting loop is formed by a single Josephson junction on one side and a chain of multiple Josephson junctions, typically ranging from 50 junctions to 500 junctions, on the other side. This chain typically functions as a linear inductor and can therefore depicted by an inductor symbol in circuit diagrams.

A flux bias 415 is threaded through the superconducting loop 411, and may be independently controlled by a suitable flux controller (such as provided by control and instrumentation system 108 and/or digital signal interface 106) which generates a flux bias signal in flux bias lines that are inductively coupled to each loop, as described above. In addition, the flux qubit 410 may be driven by a suitable microwave controller (such as provided by control and instrumentation system 108 and/or digital signal interface 106) which generates a microwave signal in drive lines that are inductively or capacitively coupled to the flux qubit 410.

FIG. 4B depicts a generalized charge qubit 420 comprising single or multiple Josephson junctions 422 in series, shunted by a capacitor 424. A fixed-frequency transmon qubit can be seen as an example of generalized charge qubit where a single Josephson junction is shunted by a large capacitor. FIG. 4C depicts a resonator 430, also referred to as harmonic oscillator, that can be realized by connecting a linear inductor 432 and capacitor 434 in parallel.

In the example of FIG. 4D, the fluxonium qubit 440 comprises a superconducting loop with a capacitor 444, a Josephson junction 442, and an inductor 443 arranged in parallel with one another. A flux bias 445 is threaded through the superconducting loop, and may be independently controlled by a suitable flux controller (such as provided by control and instrumentation system 108 and/or digital signal interface 106) which generates a flux bias signal in flux bias lines that are inductively coupled to each loop, as described above. In addition, the fluxonium qubit 440 may be driven by a suitable microwave controller (such as provided by control and instrumentation system 108 and/or digital signal interface 106) which generates a microwave signal in drive lines that are inductively or capacitively coupled to the fluxonium qubit 440.

FIG. 5A depicts an illustrative implementation of the qubit-coupler-qubit system 300 shown in FIG. 3A, according to some embodiments. In system 500, the qubits and the dual-mode coupler are implemented as superconducting circuits. In the example of FIG. 5A, fluxonium qubits 502 and 504 are connected to a coupler 505. The qubits 502 and 504 may each be implemented, for example, as the fluxonium qubit 440 shown in FIG. 4D. The dual-mode coupling circuit comprises a sub-circuit 506 that is connected to two nodes 514 and 516. Node 514 is connected to capacitor 520 that is connected to ground 522, and node 516 is connected to capacitor 524 that is connected to ground 526. A sub-circuit 508 is connected to a node 518 that has a coupler mode associated a superconducting phase φ₅₁₈ at node 518. The sub-circuit 506 has a coupler mode associated with a phase difference (φ₅₁₄−φ₅₁₆) across node 514 and node 516. Capacitors 510 are distributed in the circuit between the nodes and the qubits and determine the capacitive coupling strengths between the qubit modes and the coupler modes. The capacitance values of the capacitors 510 may be different from each other.

FIG. 5B depicts an illustrative implementation of a dual-mode coupler, according to some embodiments. In the example of FIG. 5B, the system 570 comprises fluxonium qubits 572 and 574 connected to a dual-mode coupling circuit 576. The qubits 572 and 574 may each be implemented, for example, as the fluxonium qubit 440 shown in FIG. 4D. The dual-mode coupling circuit comprises a sub-circuit connected between nodes 584 and 586. Node 584 is connected to a sub-circuit 578 that is shunted by a capacitor 592 and connected to ground 590. Node 586 is connected to a sub-circuit 582 that is shunted by a capacitor 594 and connected to ground 596. At least one sub-circuit of the sub-circuits 578, 580, and 582 comprises single or multiple Josephson junctions and the remaining sub-circuits of the sub-circuits 578, 580, and 582 can comprise inductors or single or multiple Josephson junctions. The dual-mode coupling circuit has a first coupler mode that is associated with a superconducting phase difference (φ₅₈₄−φ₅₈₆) across nodes 584 and 586 and a second coupler mode that is associated with a superconducting phase sum (φ₅₈₄+φ₅₈₆) across nodes 584 and 586. This distinct characteristic of the modes (one is associated with the phase difference between the nodes, the other associated with the phase sum of the nodes) results in the sign difference between the effective couplings provided by the first and second coupler modes. Capacitors 598 are distributed in the circuit between the nodes and the qubits and determine the capacitive coupling strengths between the qubit modes and the coupler modes. Additional capacitors 588 shunting the sub-circuit 580 can be added to the dual-mode coupling circuit to engineer the level structures of the coupler modes, enhancing the performance of the two-qubit gate. More specifically, adjusting the energy levels of the coupler modes allows modification of the coupler flux bias where the qubit-qubit coupling (“the coupling-off flux bias” or “idle operating regime”) is effectively turned off. For example, the coupling-off flux bias can be changed from 0.25 Φ₀ to 0 Φ₀ or 0.5 Φ₀, which are first-order flux-insensitive points, making the qubit-qubit coupling less sensitive to flux noise or flux pulse distortion.

Each of the sub-circuits 506 and 508 shown in FIG. 5A, and the sub-circuits 578, 580 and 582 shown in FIG. 5B, may be implemented as the illustrative sub-circuits 530, 537, 540, 550 or 560 shown in FIG. 5C, 5D, 5E, 5F or 5G, respectively. Each of these sub-circuits may be implemented as any of the five depicted sub-circuits 530, 537, 540, 550 or 560, although preferably at least one of sub-circuits 530 or 540 is present in system 500 or in system 570, since these sub-circuits allow for a flux to be threaded through a superconducting loop within the dual-mode coupler, whereas sub-circuits 537, 550 and 560 do not.

FIG. 5C depicts a sub-circuit 530 comprising single or multiple Josephson junctions 534 connected in series with single or multiple Josephson junctions 536 shunted by a capacitor 532. A magnetic flux 591 is threaded through the lower superconducting loop (i.e., bounded by the Josephson junction(s) 534 and the Josephson junction(s) 536).

FIG. 5D depicts a sub-circuit 537 comprising single or multiple Josephson junctions 539 connected shunted by a capacitor 538.

FIG. 5E depicts a sub-circuit 540 that is connected to ground 548 and comprises a set of one or more Josephson junctions 542 connected in series to single or multiple Josephson junctions 546 shunted by a capacitor 544. In addition, a with a magnetic flux 595 is threaded through the left superconducting loop (i.e., bounded by the Josephson junction(s) 542 and the Josephson junction(s) 546).

FIG. 5F depicts a sub-circuit 550 that is connected to ground 556 and comprises a set of one or more Josephson junctions 552 shunted by a capacitor 554. FIG. 5G depicts a sub-circuit 560 that is connected to ground 566 and comprises a linear inductor 562 and a capacitor 564 connected in parallel.

More generally, the coupler 306 may comprise a first circuit portion that includes two or more Josephson junctions connected in series over a first closed path without any capacitors in the first closed path and a second circuit portion including two or more Josephson junctions connected in series over a second closed path without any capacitors in the second closed path. FIGS. 5C-5G provide non-limiting, illustrative examples of how such a coupler may be implemented.

In some examples of the systems depicted in FIGS. 5A and 5B comprising the sub-circuits shown in FIGS. 5C-5G, the coupling circuit can comprise a first circuit portion that includes two or more Josephson junctions connected in series over a first closed path without any capacitors in the first closed path and a second circuit portion including two or more Josephson junctions connected in series over a second closed path without any capacitors in the second closed path. In some examples, the system can comprise the first circuit portion coupled to the first fluxonium qubit circuit through a first node and coupled to the second fluxonium qubit circuit through a second node different from the first node, and the second circuit portion coupled to the first fluxonium qubit circuit through a third node and coupled to the second fluxonium qubit circuit through the third node. In some examples, first circuit portion of FDF system can include a first capacitor that connects a first portion of the first closed path and a second portion of the first closed path, and the second circuit portion of the FDF system can include a second capacitor that connects a first portion of the second closed path and a second portion of the second closed path. These circuit designs having two separate coupling circuits for the implementation of a dual-mode coupler instead of a single coupling circuit, as depicted in FIG. 5B, offer increased design flexibility by providing a greater number of circuit parameters to manipulate. This design flexibility may enhance the adaptability of the circuit to specific performance requirements or operational environments.

In some examples of the FDF system depicted in FIG. 5B, the qubit coupling circuit can comprise a first non-ground node, and a second non-ground node, and two or more Josephson junctions connected in series over a path between the first non-ground node and the second non-ground node. In some examples, capacitors can be included in the path between the first non-ground node and the second non-ground node. This circuit design can have one or more of the following advantages. These circuit designs having a single-coupling circuit for the implementation of a dual-mode coupler instead of two separate coupling circuits, as shown in FIG. 5A, offer design simplicity, which may reduce the footprint of the physical circuit size.

In some examples, the sign of the coupler-mediated coupling is also determined by the sign of the energy difference between the qubit states (e.g., |2100 [symbol] and |1200 [symbol] in FIG. 3C) and the coupler-excited state (e.g., |1101 [symbol] or |1110 [symbol] in FIG. 3C). Specifically, flipping the sign of an energy difference by biasing the coupler-excited state higher or lower than the qubit states can result in flipping the sign of coupler-mediated coupling.

In some implementations of a FDF system, the frequencies of the high-frequency MAP transitions can be tuned by applying a low-frequency magnetic flux to the coupling circuit. FIG. 6 shows a prophetic plot of the frequencies of MAP transitions of an example FDF system as a function of magnetic flux applied to the coupling circuit. The MAP transitions are labeled by LOW, MID, HIGH, and VERY HIGH, based on their relative frequencies. The CPhase gate can be implemented by driving one of these MAP transitions. The frequencies of certain MAP transitions are tunable by adjusting the magnetic flux threading the superconducting loop of a coupling circuit.

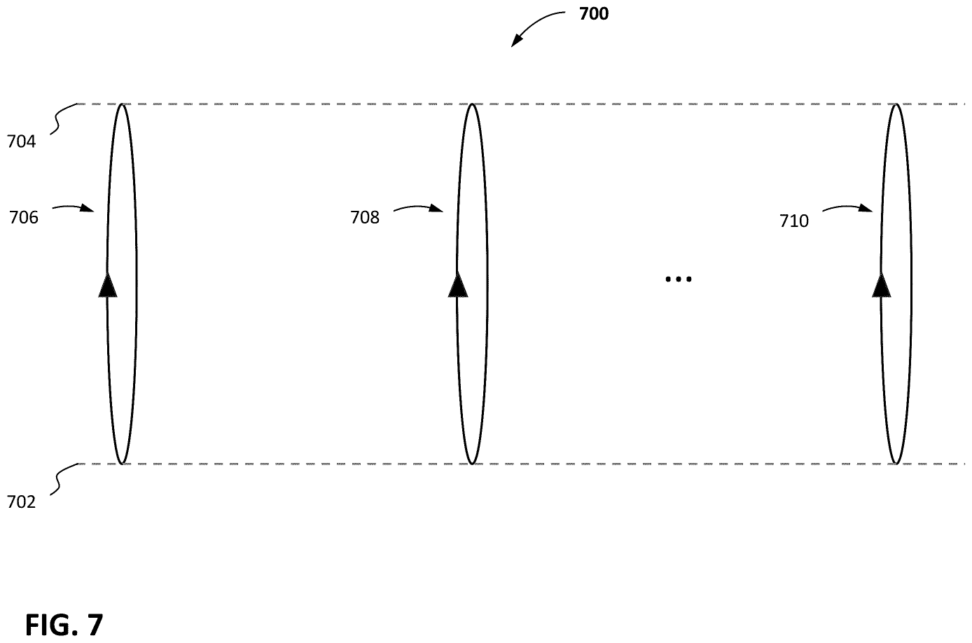

In some examples of a quantum computing system, multiple pairs of qubits can share the same MAP transition frequency. FIG. 7 depicts an example system 700 in which multiple qubit pairs share the same MAP transition frequencies 706, 708, 710 between a level 702 and a level 704. In this example system 700, the MAP transition frequencies 706, 708, 710 each correspond to an arbitrary pair of qubits, qubit i and qubit j, where i and j are integers. This commonality allows for the implementation of CPhase gates on multiple qubits or multiple qubit pairs using a single microwave tone, which can greatly simplify the overall control hardware setup for controlling a multi-qubit system at scale. For instance, the number of microwave sources, mixers, or the number of coax cables routing from the source to the chip can be reduced by enabling multiple qubits or couplers to share a common high-frequency (microwave) drive line.

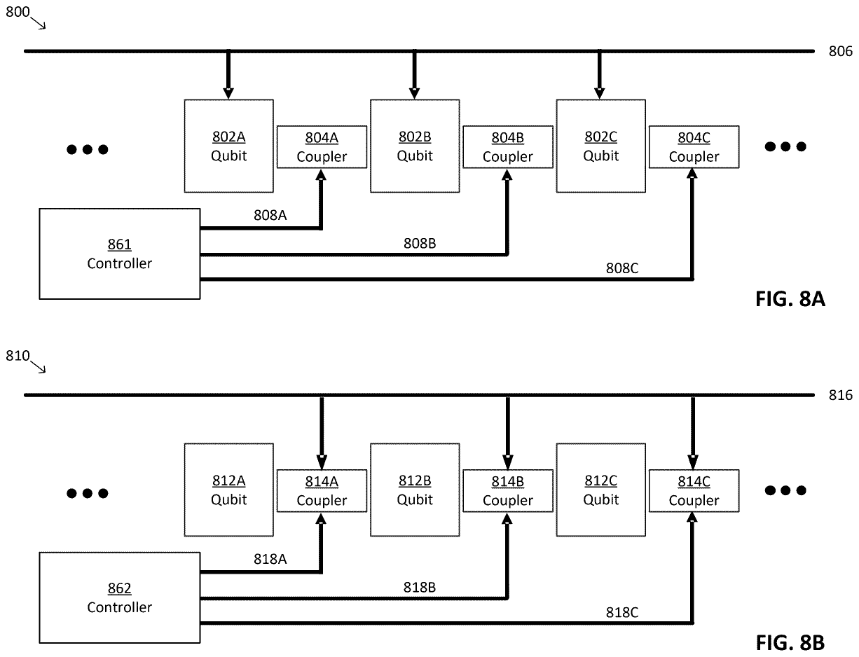

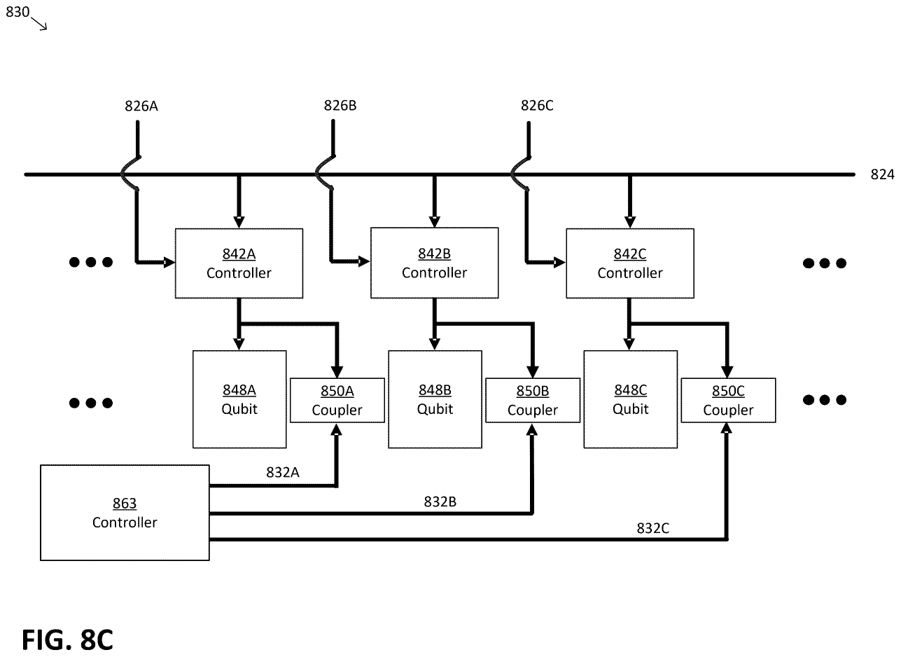

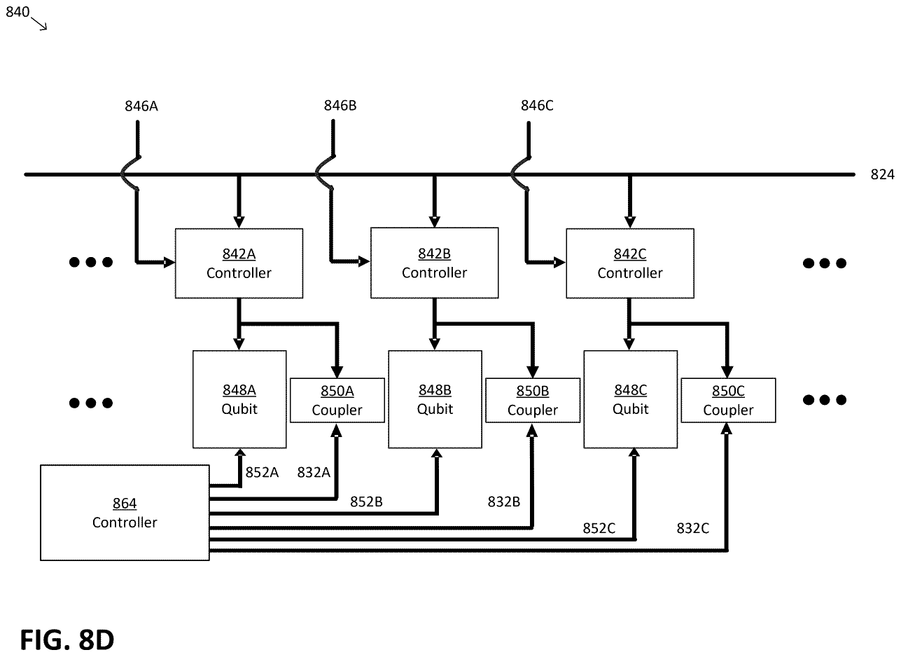

FIGS. 8A-8D are schematics of illustrative quantum computing systems in which entangling gates may be performed between qubits using a shared microwave source, according to some embodiments. Systems 800, 810, 830 and 840 are examples of quantum computing systems comprising multiple instances of system 500 or system 570, and further includes control hardware configured to adjust the coupling strength between qubits (e.g., by controlling the flux through a coupler) and to perform entangling gates between qubits.

In the example of FIG. 8A, system 800 includes qubits 802A, 802B and 802C, and couplers 804A, 804B and 804C that couple together pairs of qubits as shown. For example, the combination of qubit 802A, coupler 804A and qubit 802B may represent system 500 in FIG. 5A, or system 570 shown in FIG. 5B. It may be presumed that a number of additional couplers and qubits may also be present in system 800, as represented by the ellipses in FIG. 8A.

In the example of FIG. 8A, the controller 861 is configured to generate an analog signal that adjusts the flux bias of a given coupler. In particular, signal 808A adjusts the flux bias of the coupler 804A, the signal 808B adjusts the flux bias of the coupler 804B, and signal 808C adjusts the flux bias of the coupler 804C. In some embodiments, the analog signals 808A, 808B and 808C may be baseband signals. In some embodiments, the controller 861 may be implemented by superconducting digital logic, such as AQFP logic.

In the example of FIG. 8A, the qubits 802A, 802B, 802C share a common high-frequency line 806. Baseband flux pulsing is applied to each of the couplers to switch the effective qubit-qubit coupling on and off through signal lines along which signals 808A, 808B, 808C propagate. The qubits 802A, 802B, 802C can be connected to the common high-frequency line 806 through either coupling inductance or coupling capacitance.

FIG. 8B depicts an example quantum computing system 810 comprising qubits 812A, 812B, 812C and couplers 814A, 814B, 814C in which the couplers 814A, 814B, 814C share a common high-frequency line 816. Baseband flux pulsing can be applied to each of the couplers to switch the effective qubit-qubit coupling on and off through signal lines along which signals 818A, 818B, 818C propagate. The couplers 814A, 814B, 814C can be connected to the common high-frequency line 816 through either coupling inductance or coupling capacitance. An advantage of driving the couplers instead of the qubits is that the high-frequency drive applied to the coupler activates the MAP transitions specifically within one qubit pair that is coupled to the driven coupler. In contrast, driving the qubits directly can cause the high-frequency drive to activate the MAP transitions on multiple qubit pairs that are coupled to the driven qubit (e.g., it can activate four qubit pairs if the qubit is coupled to four nearest neighbors).

In the example of FIG. 8B, the controller 862 is configured to generate an analog signal that adjusts the flux bias of a given coupler. In particular, signal 818A adjusts the flux bias of the coupler 814A, the signal 818B adjusts the flux bias of the coupler 814B, and signal 818C adjusts the flux bias of the coupler 814C. In some embodiments, the analog signals 818A, 818B and 818C may be baseband signals. In some embodiments, the controller 861 may be implemented by superconducting digital logic, such as AQFP logic.

In some implementations of a quantum computing system microwave mixers, such as in-phase and quadrature (I/Q) mixers, can be used to convert a coherent microwave tone sent through the common high-frequency line into microwave pulses by mixing the signal with a pulsed low frequency signal. This mixing can effectively switch the microwave driving applied to the qubits or couplers on and off, thereby avoiding errors from inadvertent microwave driving of qubits or couplers when they are not supposed to interact with the high-frequency (microwave) drive. Additionally, mixers can allow for frequency up-conversion and down-conversion up to a few hundred MHz. This capability enables fine-tuning of the drive frequency for each qubit pair to avoid driving undesired transitions. These undesired transitions can include high-order parasitic leakage transitions or two-level defects that are in resonance with the MAP transition frequency.

FIG. 8C is a schematic of an illustrative quantum computing system in which entangling gates may be performed between qubits using a shared microwave source, according to some embodiments. System 830 is an example of a quantum computing system comprising multiple instances of system 500 or system 570, and further includes control hardware configured to adjust the coupling strength between qubits (e.g., by controlling the flux through a coupler) and to perform entangling gates between qubits.

In the example of FIG. 8C, system 830 includes qubits 848A, 848B and 848C, and couplers 850A, 850B and 850C that couple together pairs of qubits as shown. For example, the combination of qubit 848A, coupler 850A and qubit 848B may represent system 300 in FIG. 3A, or system 500 shown in FIG. 5A. It may be presumed that a number of additional couplers and qubits may also be present in system 830, as represented by the ellipses in FIG. 8C.

In the example of FIG. 8C, the controller 863 is configured to generate an analog signal that adjusts the flux bias of a given coupler. In particular, signal 832A adjusts the flux bias of the coupler 850A, the signal 832B adjusts the flux bias of the coupler 850B, and signal 832C adjusts the flux bias of the coupler 850C. In some embodiments, the analog signals 832A, 832B and 832C may be baseband signals. In some embodiments, the controller 863 may be implemented by superconducting digital logic, such as AQFP logic.

In the example of FIG. 8C, controllers 842A, 842B and 842C are each coupled to a shared microwave line 824 and are configured to produce a microwave pulse based on received signals 826A, 826B and 826C, respectively. In some embodiments, the signals 826A, 826B and 826C may be pulse envelope signals that indicate when (and optionally, at what amplitude) a microwave signal should be produced from the controllers 842A, 842B and 842C, respectively. The microwave pulses produced may be directed to one of the qubits and/or one of the couplers as shown to drive the qubit and/or coupler between energy states. As described above, by generating microwave pulses from a shared microwave signal, a single microwave source may be shared by many, or even all, qubits and couplers, leading to much simpler control hardware.

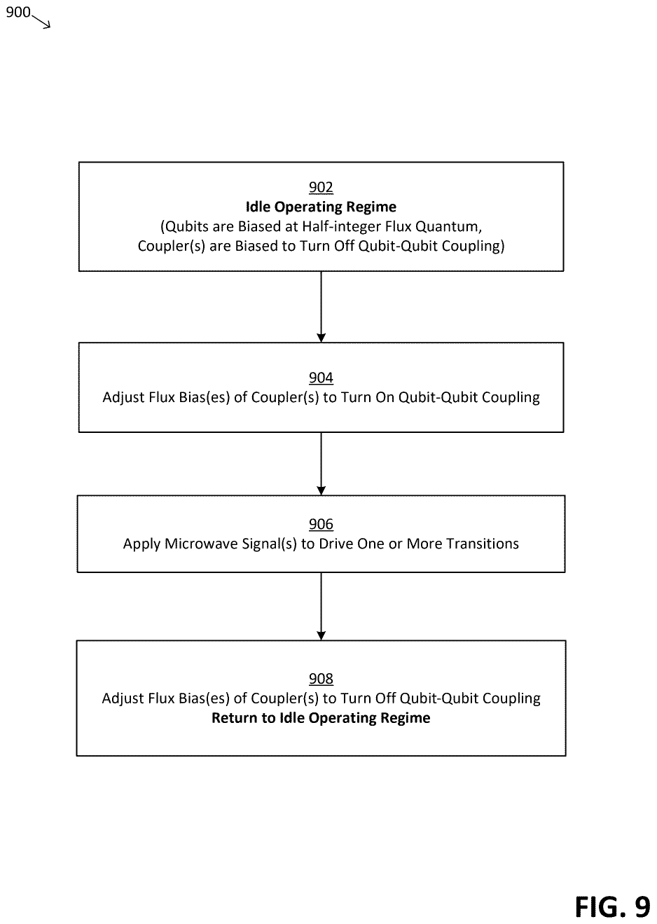

FIG. 8C is an example of such an approach in that system 830 may be implemented in digital logic coupled to a single microwave source. For example, the signals 826A, 826B and 826C may be generated by a suitable superconducting digital logic controller (not shown in FIG. 8C), and controller 863 may be implemented by the same, or by a different, superconducting digital logic controller. As a result, a single (or at least, fewer) microwave signals may be supplied to the low temperature stage of the system, which utilizes such a signal in combination with digital hardware to control the coupling between qubits and perform entangling gates between the qubits, though a process as described below in relation to FIG. 9.

According to some embodiments, system 830 may be configured to perform entangling gates between qubits by driving one or more of the couplers 850A, 850B or 850C, and/or one or more of the qubits 848A, 848B or 848C. An advantage of driving the couplers instead of the qubits is that the microwave pulse applied to the coupler activates the MAP transitions specifically within one qubit pair that is coupled to the driven coupler. In contrast, driving the qubits directly can undesirably cause the high-frequency drive to activate the MAP transitions on multiple qubit pairs that are coupled to the driven qubit (e.g., it can activate four qubit pairs if the qubit is coupled to four nearest neighbors).

According to some embodiments, controllers 842A, 842B and 842C each is, or comprises, a microwave mixer (which may include a digital mixer, an analog mixer, or a hybrid analog and digital mixer). For instance, each of controllers 842A, 842B and 842C may consist of, or may comprise, an in-phase and quadrature (I/Q) mixer that is configured to generate a microwave pulse by mixing the coherent microwave tone sent through the shared line 824 with pulsed low frequency signal 826A, 826B or 826C, respectively. This mixing effectively allows the signals 826A, 826B and 826C to switch the microwave drives applied to the qubits and/or couplers on and off, thereby avoiding errors from inadvertent microwave driving of qubits or couplers when they are not intended to interact with the high-frequency (microwave) drive. In some embodiments, each of controllers 842A, 842B and 842C may be configured to perform frequency up-conversion and/or down-conversion of the microwave line 824 (e.g., by up to a few hundred MHz) to fine-tune frequencies of microwave pulses applied to each qubit and/or coupler to thereby avoid driving undesired transitions. These undesired transitions can include high-order parasitic leakage transitions or two-level defects that are in resonance with the MAP transition frequency.

In some embodiments, one or more of the controllers 842A, 842B and 842C may be configured to generate shaped microwave drives that are applied to the qubits or/and couplers to perform gates. Shaped drives may in at least some cases suppress non-adiabatic gate errors. In some cases, one or more of the controllers may be configured to perform fast adiabatic pulse shaping to generate a microwave pulse from the shared microwave signal line 824. According to some embodiments, one or more of the controllers 842A, 842B and 842C may be configured to generate microwave drives that are shaped to be symmetric, with equal positive and negative areas resulting in a net pulse area of zero. This net-zero pulse shaping can help suppress the effects of pulse distortion that come from various factors, including hardware imperfections.

In some embodiments, the controller 863 may be configured to generate shaped baseband flux pulses to the couplers. Shaped flux pulses may in at least some cases suppress non-adiabatic gate errors, such as leakages from computational states to non-computational states. According to some embodiments, the controller 863 may be configured to generate baseband flux pulses that are shaped to be symmetric, with equal positive and negative areas resulting in a net pulse area of zero. This net-zero pulse shaping can help suppress the effects of pulse distortion that come from various factors, including hardware imperfections.

In some implementations, machine learning techniques such as reinforcement learning can be utilized to optimize the shapes of control pulses for single and two-qubit gates. The cost function includes various types of gate errors such as leakage errors, coherent errors, and incoherent errors. Gate errors can be quantified by measuring the outputs of quantum circuits where the expected ideal outcomes (assuming no errors in the applied gates) can be predicted using classical computers. The optimizer controls pulse parameters to determine the overall pulse shape, as well as parameters for the extra corrective single-qubit gate operations that cancel out unwanted single-qubit rotations induced by the applied control pulse. Optimizing the pulse shape may optimize the spectral distribution of the pulse to minimize inadvertent driving of nearest undesired level transitions.

FIG. 8D depicts an example quantum computing system 840 in which controllers 842A, 842B, 842C are each coupled to a shared microwave line 824 and are configured to produce a microwave pulse based on received signals 846A, 846B, 846C, respectively. Each controller 842A, 842B, 842C is connected to a respective coupler 850A, 850B, 850C. Couplers 850A, 850B, 850C are connected to qubits 848A, 848B and 848C. Baseband flux pulsing is applied through signals 852A, 852B, 852C generated by controller 864 to couplers 850A, 850B, 850C.

The example of FIG. 8D is the same as the example of FIG. 8C but for the additional signals 852A-C, which allows controller 864 to provide signals to the qubits 848A-C in addition to the couplers 850A-C. An advantage of driving the couplers instead of the qubits is that the high-frequency drive applied to the coupler activates the MAP transitions specifically within one qubit pair that is coupled to the driven coupler. In contrast, driving the qubits directly can cause the high-frequency drive to activate multiple qubit pairs that are coupled to the driven qubit.

Even if device parameters deviate from target parameters due to fabrication variations, aligning the MAP transitions frequencies of multiple qubit pairs to resonance is achievable through precise tuning of the magnetic fluxes in the relevant coupling circuits.

FIG. 9 is a flowchart of a method of performing an entangling gate, according to some embodiments. Method 900 may be performed by system 100, which includes one or more instances of the qubit-coupler-qubit system shown in FIG. 3A. For the purposes of explanation, a single instance of the qubit-coupler-qubit system 300 will be assumed below, although in general the method may be performed for any number of such systems.

Method 900 includes act 902 in which the qubit 302 and qubit 308 are flux-biased at, or at approximately at, 0.5Φ₀—the so-called “sweet spot.” Moreover, the flux bias of the coupler 306 is tuned so that the coupling between qubit 302 and qubit 308 is sufficiently low to be turned off. In some embodiments, the flux bias of the coupler 306 may be adjusted by directing a flux bias signal (e.g., a current signal) along a flux bias line that is inductively coupled to a superconducting loop of the coupler (e.g., inductively coupled via an antenna). For instance, the coupler may be implemented as shown in FIG. 5A or FIG. 5B, using any of the sub-circuits 530, 537, 540, 550 or 560 shown in FIGS. 5C-5G, and the flux bias line may be inductively coupled to the superconducting loop of the sub-circuit.

In act 904, the flux bias of the coupler 306 is adjusted by directing a flux bias signal (e.g., a current signal) along a flux bias line that is inductively coupled to a superconducting loop of the coupler (e.g., inductively coupled via an antenna). In act 904, the flux bias of the coupler is adjusted so that a transition between states of the coupler is resonant with a transition between states of the qubits, thereby producing a coupling between the qubits via the coupler. Act 904 may also comprise adjusting the flux bias of the coupler so that only one state of the dual-mode coupler is resonant with the transition between states of the qubits, since bringing the coupler modes closer to one another may turn off the qubit-qubit coupling.

For example, as shown in FIG. 3B, if the transition frequency between the |1 [symbol] and |2 [symbol] states of the qubits, and the transition frequency between the |0 [symbol] and |1 [symbol] states of the coupler, are resonant, then the |2100 [symbol] , |1200 [symbol] states will be resonant with the |1101 [symbol] and |1110 [symbol] states, thereby producing a coupling between the qubits via the dual-state coupler.

Due to the above-described level hybridization between the states as shown in FIGS. 3D-3G, transitions between states of the qubits and the coupler may be driven selectively by applying a microwave pulse through one or more charge lines that are capacitively coupled to qubit 302, qubit 308 or coupler 306. Alternatively, the transitions may be driven through one or more flux lines that are inductively coupled to qubit 302, qubit 308 or coupler 306. Act 906 comprises applying any number of such microwave pulses to the qubit 302, qubit 308 and/or coupler 306 to perform desired operations, including entangling gate operations. In some embodiments, act 906 comprises performing an entangling gate by applying a microwave pulse to the coupler 306.

In act 908, the flux bias of the coupler is adjusted so that a transition between states of the coupler is no longer resonant with a transition between states of the qubits, thereby reducing (or removing) the coupling between the qubits via the coupler. Act 908 may also comprise adjusting the flux bias of the coupler so that only the states of the dual-mode coupler are not resonant with one another, since bringing the coupler modes closer to one another may also reduce qubit-qubit coupling.

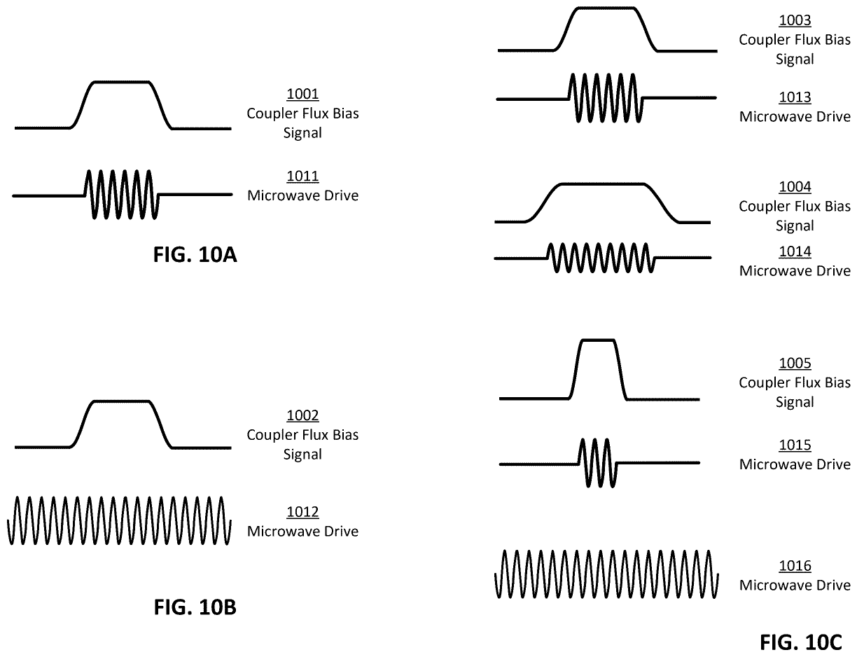

FIGS. 10A-10C depict examples of various approaches to generating signals for adjusting the flux bias of a coupler, and for driving a qubit and/or the coupler to perform an entangling gate, according to some embodiments. For example, the system 830 may be operated to produce the depicted coupler flux bias signals 1001, 1002, 1003, 1004 and 1005 by operating controller 863, and to produce the depicted microwave drives 1011, 1012 and 1013 by operating one of the controllers 842A, 842B or 842C.

In the example of FIGS. 10A and 10B, two-qubit gate pulse sequences are depicted for implementing entangling gates (e.g., CPhase gates), also referred to herein as Baseband and Microwave Activated Phase (BMAP) gates. As described above, The flux pulse applied to the coupler circuits controls the effective coupling strength between the qubits' higher excited states (e.g., |2100 [symbol] and |1200 [symbol] ) by adjusting the energies of the coupler excited states (e.g., |1101 [symbol] and |1110 [symbol] ). Throughout the gate operation, the flux biases of fluxonium qubits may be set to half-integer magnetic flux quantum values to maintain its high coherence times. Additional flux pulses can be applied to the qubits to compensate for any unwanted flux crosstalk induced by the flux pulse applied to the coupler circuits. The microwave pulse applied to the qubits and/or coupler circuits drives one or more of the MAP transitions. The pulsed microwave drive 1011 can be delivered to the coupler and/or to qubit(s) through either the flux or charge lines of the qubits and/or coupler. Instead of generating a microwave pulse as shown in FIG. 10A (e.g., by shaping a common microwave signal as described in the example of FIGS. 8A-8D above), a continuous microwave tone as shown in FIG. 10B can instead be applied to a qubit and/or coupler, which eliminates the need for components for shaping microwave signals. This approach may be feasible because the coupler can address any two-qubit gate errors coming from always-on microwave signals by effectively turning off the qubit-qubit interactions.

FIG. 10C shows an example pulse sequence implementing multiple CPhase gates in a resource-efficient manner by sharing a common microwave drive 1016 for multiple qubit pairs. Microwave drives 1013, 1014 and 1015 may be generated by shaping the common microwave drive 1016 using the flux bias signals 1003, 1004 and 1005, respectively, as a shaping envelope. The resulting flux bias signals may be applied to respective couplers to control the effective coupling strengths for each qubit pair. The amplitude, shape, and duration of each flux bias signal may be selected to optimize the performance of the two-qubit gate on each qubit pair. The microwave pulse or tone applied through the shared common microwave drive line drives one or more of the MAP transitions, implementing a CPhase gate on each qubit pair. Because the number of microwave sources and the cables routing from the source to the chip can be significantly reduced by sharing the microwave drive line, this scheme may be referred to as a resource-efficient Baseband and Microwave Activated Phase (BMAP) gate.

As described above, some quantum computer systems may include a control and instrumentation system that generates and manipulates control waveforms, part or all of which can be housed in a dilution refrigerator and co-located with the qubits and couplers. Such a system may be referred to as a cold control system. For example, a cold control system may be implemented by superconducting digital logic circuits, a type of electronic circuitry that utilize superconducting materials to possibly enable energy-efficient and high-performance digital signal processing. Examples of suitable superconducting digital logic circuits are described above.

In superconducting digital logic circuits, information is typically stored, processed, and transferred in the form of a single quantum of magnetic flux, also referred to as single flux quantum (SFQ), in various superconducting loops. In Rapid Single Flux Quantum (RSFQ) logic and Reciprocal Quantum Logic (RQL), which are other SFQ logic approaches related to AQFP logic, a Josephson junction is “flipped” (i.e., switched into a dissipative voltage state) during the operation. Once the junction is flipped, one does not have control over the dynamics, whereas in AQFP dynamics may be better controlled. One or more AQFP circuits can be combined into a digital-to-analog converter (DAC) that takes digital input and converts it into baseband flux pulses to control the quantum system, e.g., couplers. The pulse may be transferred to the coupler by mutually inductively coupling the AQFP and the coupler circuit.

In some examples, firmware protocols can be used to control AQFP circuits to perform multiplexing, set trim SQUIDs, etc. In general, software infrastructure can be used to compile a set of gates into AQFP architecture control pulses so that timing, amplitude, and idling are properly scheduled and synchronized.

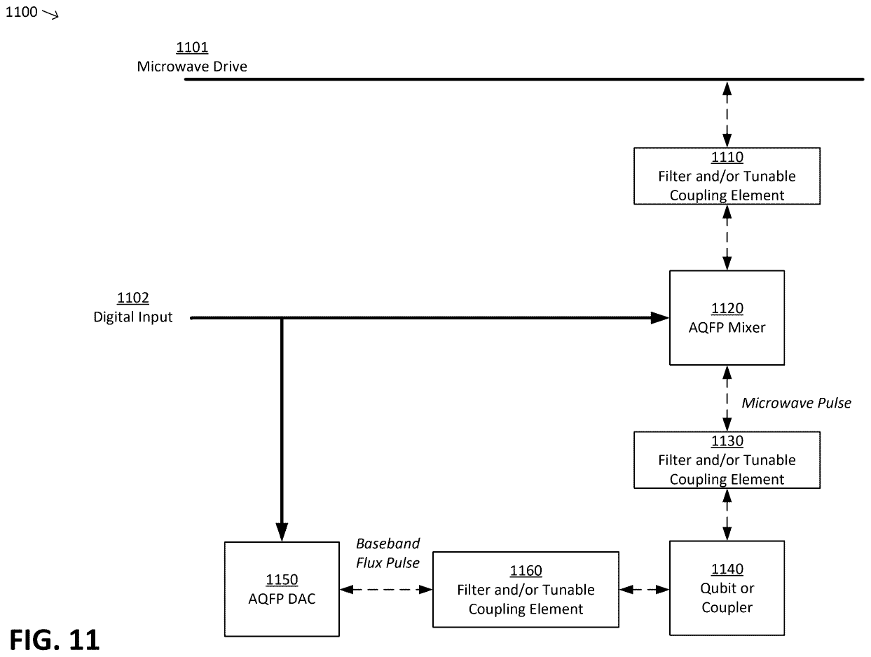

FIG. 11 illustrates one implementation of such a cold control system 1100 for the implementation of the BMAP gate, based on AQFP circuits. System 1100 may for instance form at least part of the digital interface 106 shown in FIG. 1, wherein the qubit or coupler 1140 forms part of the qubits 102.

In the example of FIG. 11, AQFP-based mixer 1120 is configured to mix a digital input signal 1102 with a continuous microwave tone from a microwave drive line 1101, thereby generating a microwave pulse according to the digital input. For example, the digital input could specify whether the microwave pulse is active or inactive, with a 0 meaning no output, and a 1 meaning the mixer should output a microwave signal. More complex methods of digital control may also be envisioned and implemented by AQFP-based mixer 1120. A filter and/or tunable coupling element 1130 (e.g., DC SQUID or RF SQUID) or trimming circuit is arranged to mediate the coupling between the AQFP-based mixer 1120 and the qubit or coupler 1140 in order to control the amplitude of the microwave pulse applied to the qubit or coupler 1140. In some embodiments, AQFP-based mixer 1120, and/or the filter and/or tunable coupling element 1130, may represent an implementation of part or all of a controller 842A, 842B or 842C shown in FIG. 8C-8D.

In the example of FIG. 11, AQFP-based DAC 1150 is configured to generate a baseband flux pulse given the digital input signal 1102. For example, the digital input could specify whether the baseband flux pulse is active or inactive, with a 0 meaning no output, and a 1 meaning the mixer should output a baseband flux signal. More complex methods of digital control may also be envisioned and implemented by AQFP-based DAC 1150, such as converting a digital waveform supplied as part of digital input signal 1102 to an analog signal. The baseband flux pulse is delivered to a qubit or coupler 1140. In the case of a coupler 1140, the baseband flux pulse signal thereby allows the system to switch the qubit-qubit effective coupling on and off. A filter and/or tunable coupling element 1160 (e.g., DC SQUID or RF SQUID) or trimming circuit is arranged to mediate the coupling between the AQFP-based DAC 1150 and the qubit or coupler 1140 in order to control the amplitude of the baseband flux pulse signal applied to the qubit or coupler 1140.

Also in the example of FIG. 11, a filter and/or tunable coupling element 1110 is arranged to filter the microwave signal from the microwave drive line 1101 before providing the filtered microwave signal to the AQFP-based mixer 1120.

Each of the elements depicted in FIG. 11 can be capacitively, inductively, or galvanically coupled to one another along the dashed arrowed lines

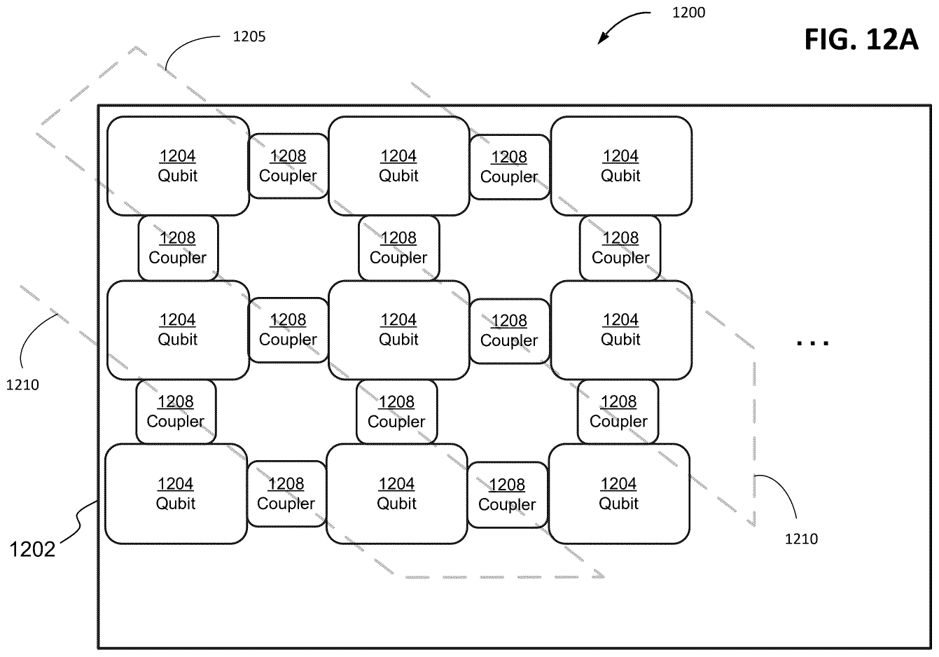

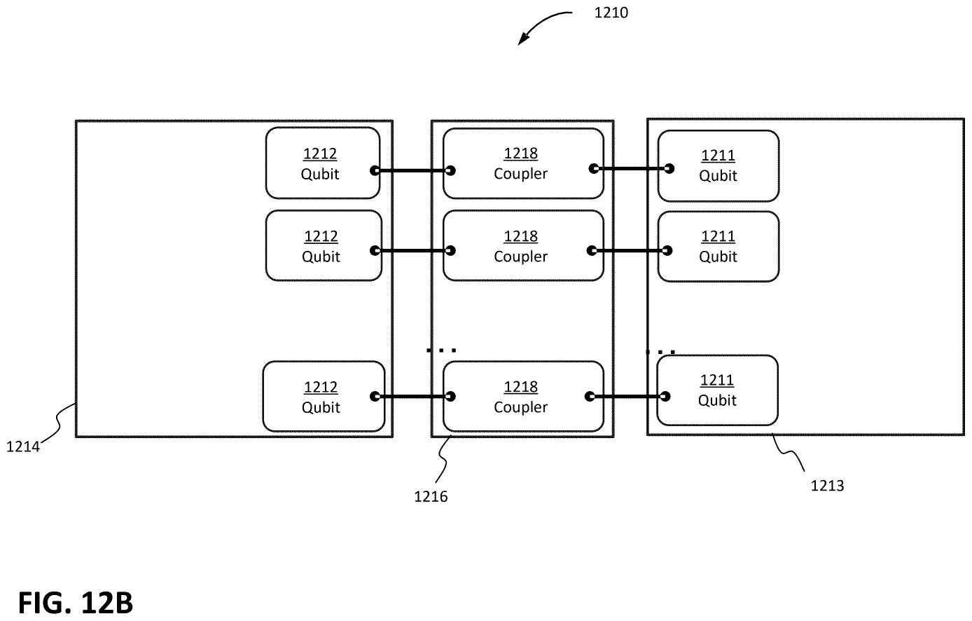

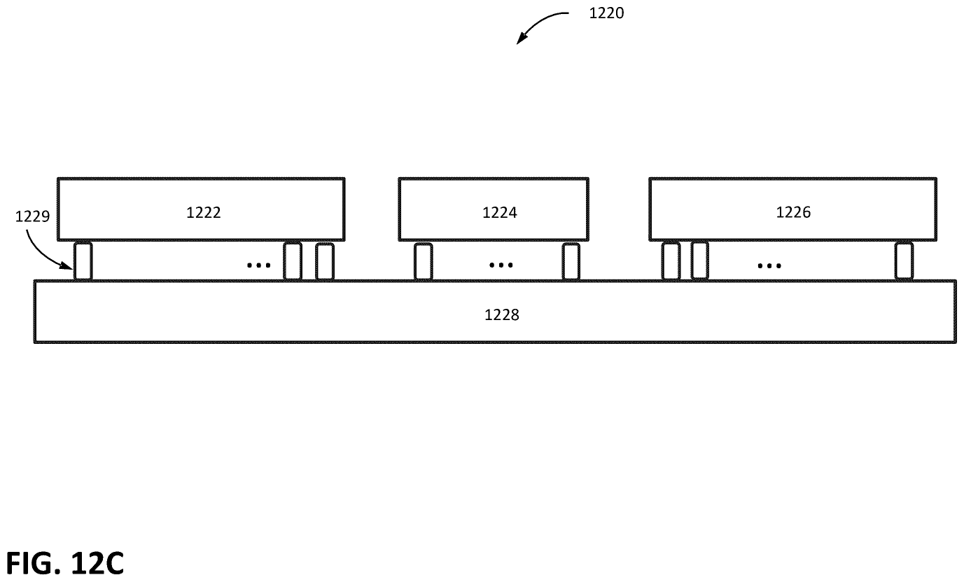

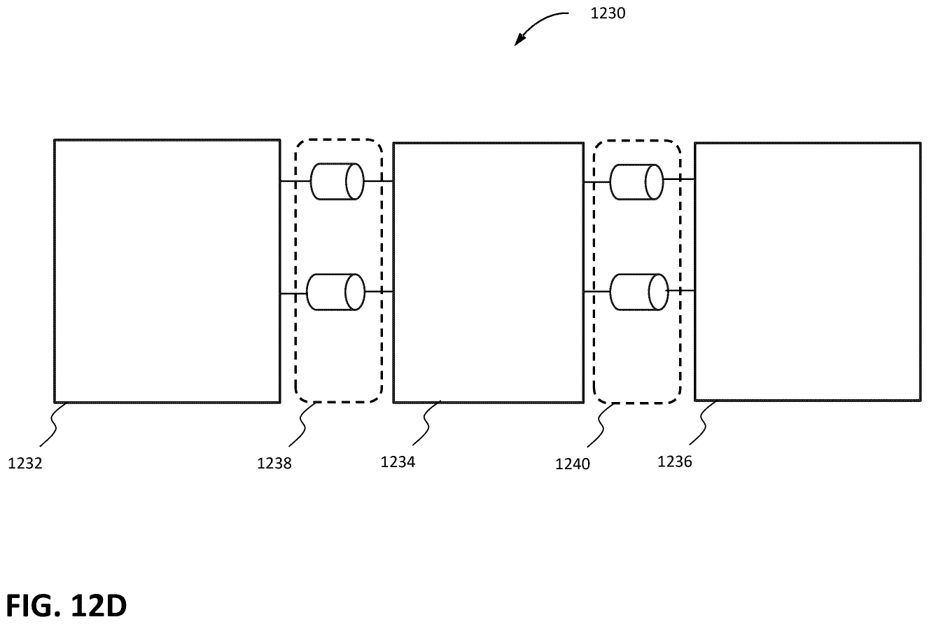

The various embodiments described above may provide a unit cell that can be tiled into a two-dimensional (2D) array of qubits. As one example, FIG. 12A contains a schematic diagram of a quantum computing architecture 1200 comprising chip 1202 on which couplers 1208 (e.g., single mode or dual-mode couplers) are interconnected with qubits 1204 and arranged in a 2D grid. In particular, in contrast to some of the above-described architectures, FIG. 12A is an example of an arrangement in which a qubit may be coupled to multiple other qubits via respective couplers. For example, the central qubit 1204 shown in FIG. 12A is coupled to four other qubits each via a different coupler. The qubit connectivity (e.g., the number of nearest-neighboring qubits coupled to a central qubit) may vary depending, for example, on the target applications or error correction schemes.

In the example of FIG. 12A, the couplers 1208 share a common microwave driveline 1205, through which either a pulsed or continuous microwave tone can be delivered to drive MAP transitions as described above. In some embodiments, each of the couplers 1208 may be arranged as shown in FIG. 11, with each respective coupler 1208 being provided as coupler 1140, and with the common microwave driveline 1205 being provided as the microwave drive line 1101 for each of the couplers 1208. Subsequent to application of a pulsed or continuous microwave tone to a coupler 1208, a two-qubit gate on each qubit pair can be activated or deactivated by dynamically adjusting the flux bias of the coupler (i.e., by applying flux pulses to the couplers). This approach can significantly reduce the number of microwave sources and the amount of routing (e.g., number of coax cables) from the signal sources to the chip on which the couplers and qubits are fabricated, enabling quantum computer scale-up with a simplified and cost-effective control hardware setup.

In some embodiments, a coupler can be made physically long, enabling non-local, long-range connections. Therefore, a quantum computer system architecture may be extended beyond a 2D grid architecture to accommodate more complex three-dimensional (3D) grids with non-local connections. FIG. 12B shows a schematic diagram of a quantum computing architecture 1210 comprising a coupler chip 1216 on which one or more couplers 1218 are arranged, and which serves as an interconnect between a first quantum processor chip 1212 comprising one or more qubits 1214 and a second quantum processor chip 1213 comprising one or more qubits 1211.

FIG. 12C illustrates an example of a 3D quantum computing device architecture 1220 comprising a first quantum processor chip 1222, a dual-mode coupler chip 1224, and a second quantum processor chip 1226 connected to single interposer layer 1228 by vertical connections 1229. These vertical connections can comprise electrically conducting bonds, for example indium bumps, with thickness on the order of tens of micrometers. These chips could also be part of a multi-chip module housing multiple superconducting circuit layers (such as SFQ or AQFP circuits) used to generate or manipulate control signals for qubits, couplers, and readout resonators.

FIG. 12D shows an example quantum computing device architecture 1230 comprising a first quantum processor chip 1232 connected to a coupler chip 1234 by a first set of one or more long resonator buses 1238 and a second quantum process chip 1236 connected to the coupler chip by a second set of one or more long resonator buses 1240. Couplers in the coupler chip can be either dual-mode couplers or single-mode couplers. The long resonator buses can have a length on the order of a few millimeters and resonator modes that are far detuned from qubit and coupler modes to prevent frequency collisions during gate operations. Depending on the type of couplers used, one or more electrical connections per interconnection may be used. For example, if the dual-mode coupling circuit illustrated in FIG. 5A is used, single (two) electrical connections is (are) used per interconnection to implement the corresponding coupling capacitance network. Depending on the length of a bus resonator, the coupler and qubit parameters may need to be adjusted accordingly to achieve optimal performance; for example, longer bus resonators might use larger coupling capacitance between the bus resonator and the coupler or between the bus resonator and the qubit.

FIGS. 12C and 12D show circuit schematics of example quantum computing systems in which two quantum processor chips are interconnected through a coupler chip where the couplers can be either dual-mode couplers or single-mode couplers. The coupler chip and quantum processor chips may be linked via long resonator buses (with a length on the order of a few millimeters) where the resonator modes are far detuned from qubit and coupler modes to prevent frequency collisions during gate operations. Depending on the type of couplers used, one or more electrical connections per interconnection may be used. For example, if the dual-mode coupling circuit illustrated in FIG. 5A is used, single (two) electrical connections is (are) used per interconnection to implement the corresponding coupling capacitance network. Depending on the length of a bus resonator, the coupler and qubit parameters may need to be adjusted accordingly to achieve optimal performance; for example, longer bus resonators might use larger coupling capacitance between the bus resonator and the dual-mode coupler or between the bus resonator and the qubit.

As referred to herein, a “qubit” includes any multi-level quantum-mechanical system capable of being controlled by a quantum information processor. The quantum states of the qubit may for instance include electronic states, polarization states, vibrational states, rotational states, or spin states. As referred to herein, a “superconducting qubit” includes any superconducting electronic circuit that may be operated as a multi-level quantum-mechanical system, such as a charge qubit (e.g., a transmon), a flux qubit (e.g., a fluxonium qubit), or a phase qubit.

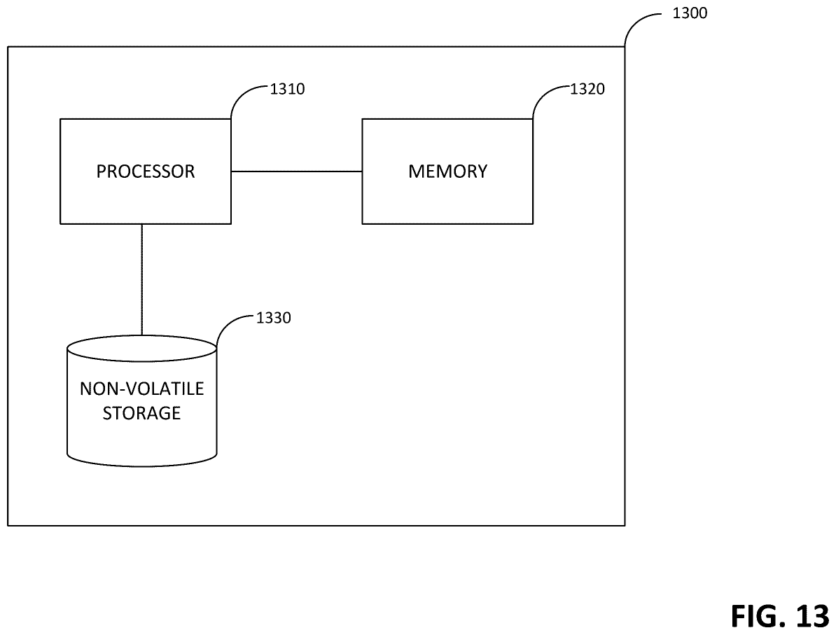

An illustrative implementation of a computer system 1300 that may be used to control a control and instrumentation system, a digital logic, an AQFP-based mixer, etc. to perform any of the techniques described above is shown in FIG. 13. The computer system 1300 may include one or more processors 1310 and one or more non-transitory computer-readable storage media (e.g., memory 1320 and one or more non-volatile storage media 1330). The one or more processors 1310 may control writing data to and reading data from the memory 1320 and the one or more non-volatile storage media 1330 in any suitable manner, as the aspects of the disclosure described herein are not limited in this respect. To perform functionality and/or techniques described herein, the one or more processors 1310 may execute one or more instructions stored in one or more computer-readable storage media (e.g., the memory 1320, storage media, etc.), which may serve as non-transitory computer-readable storage media storing instructions for execution by the one or more processors 1310.

In connection with techniques described herein, code used to, for example, generate digital data to control generation of a flux bias signal or a microwave pulse, etc. may be stored on one or more computer-readable storage media of computer system 1300. The one or more processors 1310 may execute any such code to perform any of the above-described techniques as described herein. Any other software, programs or instructions described herein may also be stored and executed by computer system 1300. It will be appreciated that computer code may be applied to any aspects of methods and techniques described herein. For example, computer code may be applied to generate digital data to control generation of a flux bias signal or a microwave pulse in response to digital data obtained from reading the state of a fluxonium qubit, etc.

The various methods or processes outlined herein may be coded as software that is executable on one or more processors that employ any one of a variety of operating systems or platforms. Additionally, such software may be written using any of numerous suitable programming languages and/or programming or scripting tools, and also may be compiled as executable machine language code or intermediate code that is executed on a virtual machine or a suitable framework.

In this respect, various inventive concepts may be embodied as at least one non-transitory computer readable storage medium (e.g., a computer memory, one or more floppy discs, compact discs, optical discs, magnetic tapes, flash memories, circuit configurations in Field Programmable Gate Arrays or other semiconductor devices, etc.) encoded with one or more programs that, when executed on one or more computers or other processors, implement the various embodiments of the present disclosure. The non-transitory computer-readable medium or media may be transportable, such that the program or programs stored thereon may be loaded onto any computer resource to implement various aspects of the present disclosure as described above.

The terms “program,” “software,” and/or “application” are used herein in a generic sense to refer to any type of computer code or set of computer-executable instructions that can be employed to program a computer or other processor to implement various aspects of embodiments as described above. Additionally, it should be appreciated that according to one aspect, one or more computer programs that when executed perform methods of the present disclosure need not reside on a single computer or processor, but may be distributed in a modular fashion among different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments.

Also, data structures may be stored in non-transitory computer-readable storage media in any suitable form. Data structures may have fields that are related through location in the data structure. Such relationships may likewise be achieved by assigning storage for the fields with locations in a non-transitory computer-readable medium that convey relationship between the fields. However, any suitable mechanism may be used to establish relationships among information in fields of a data structure, including through the use of pointers, tags or other mechanisms that establish relationships among data elements.

Having thus described several aspects of at least one embodiment of this disclosure, it is to be appreciated that various alterations, modifications, and improvements will readily occur to those skilled in the art. For instance, aspects of the techniques described herein may be combined in any of the following ways:

Aspect 1. A system comprising: a first fluxonium qubit; a second fluxonium qubit; a coupling circuit coupled to each of the first fluxonium qubit and the second fluxonium qubit, the coupling circuit exhibiting at least two modes; and at least one controller configured to adjust one or more energy levels of the at least two modes of the coupling circuit to thereby increase or decrease a coupling strength between the first fluxonium qubit and the second fluxonium qubit via one or more of the at least two modes of the coupling circuit.

Aspect 2. The system of aspect 1, wherein the at least one controller is configured to adjust the one or more energy levels of the at least two modes of the coupling circuit by controlling a magnetic flux bias threaded through a superconducting loop of the coupling circuit.

Aspect 3. The system of aspect 1, wherein the coupling circuit is capacitively coupled to the first fluxonium qubit, and is, independent of the capacitive coupling to the first fluxonium qubit, capacitively coupled to the second fluxonium qubit.

Aspect 4. The system of aspect 1, wherein the coupling circuit comprises a first superconducting sub-circuit, and a second superconducting sub-circuit connected in parallel with the first superconducting sub-circuit.

Aspect 5. The system of aspect 4, wherein the first superconducting sub-circuit comprises a plurality of Josephson junctions connected in parallel with at least one capacitor.

Aspect 6. The system of aspect 4, wherein the second superconducting sub-circuit comprises a plurality of Josephson junctions connected in parallel with at least one capacitor.

Aspect 7. The system of aspect 4, wherein the second superconducting sub-circuit comprises a linear inductor connected in parallel with at least one capacitor.

Aspect 8. The system of aspect 4, wherein the first fluxonium qubit is capacitively coupled to each of the first superconducting sub-circuit and the second superconducting sub-circuit in parallel, and wherein the second fluxonium qubit is capacitively coupled to each of the first superconducting sub-circuit and the second superconducting sub-circuit in parallel.

Aspect 9. The system of aspect 1, wherein the coupling circuit is coupled to ground.

Aspect 10. The system of aspect 1, wherein the coupling circuit comprises one or more Josephson junctions connected in parallel to at least one capacitor.

Aspect 11. The system of aspect 10, wherein the one or more Josephson junctions are connected to the first fluxonium qubit via a first capacitor, and wherein the one or more Josephson junctions are connected to the second fluxonium qubit via a second capacitor.

Aspect 12. The system of aspect 1, wherein the at least one controller is configured to perform an entangling gate between the first fluxonium qubit and the second fluxonium qubit by applying at least one microwave pulse to at least one of the first fluxonium qubit, the second fluxonium qubit and the coupling circuit.

Aspect 13. The system of aspect 1, wherein the at least one controller is configured to adjust the one or more energy levels of the at least two modes of the coupling circuit to reduce the coupling strength between the first fluxonium qubit and the second fluxonium qubit to zero.

Aspect 14. The system of aspect 1, wherein the coupling circuit is a superconducting circuit.

Aspect 15. A method comprising: controlling a flux bias of a coupling circuit, wherein the coupling circuit is coupled to a first fluxonium qubit and a second fluxonium qubit and exhibits at least two modes, wherein controlling the flux bias of the coupling circuit increases a coupling strength between the first fluxonium qubit and the second fluxonium qubit via one or more of the at least two modes of the coupling circuit; and applying at least one microwave pulse to at least one of the first fluxonium qubit, the second fluxonium qubit and the coupling circuit to perform an entangling gate between the first fluxonium qubit and the second fluxonium qubit.

Aspect 16. The method of aspect 15, wherein controlling the flux bias of the coupling circuit comprises controlling a magnetic flux bias threaded through a superconducting loop of the coupling circuit.

Aspect 17. The method of aspect 15, wherein controlling the flux bias of the coupling circuit hybridizes at least one energy level of the at least two modes of the coupling circuit with an energy level of the first fluxonium qubit and an energy level of the second fluxonium qubit.

Aspect 18. An apparatus for quantum computing comprising: a first fluxonium qubit circuit; a second fluxonium qubit circuit; a qubit coupling circuit, where: the first fluxonium qubit circuit and the second fluxonium qubit circuit are each connected to the qubit coupling circuit such that energy levels associated with each of the first fluxonium qubit circuit, the second fluxonium qubit circuit, and the qubit coupling circuit form a hybridized quantum system comprising a computational subspace and a non-computational subspace, and the qubit coupling circuit is configured to include a coupling suppression state between the first fluxonium qubit circuit and the second fluxonium qubit circuit; a low-frequency control module configured to apply a low-frequency electromagnetic signal to the qubit coupling circuit; and a high-frequency control module configured to apply a high-frequency electromagnetic signal having an amplitude, a frequency, an envelope shape, and a duration to at least one of the first fluxonium qubit circuit, the second fluxonium qubit circuit, or the qubit coupling circuit, where the frequency of the high-frequency electromagnetic signal is higher than a frequency of the low-frequency electromagnetic signal.

Aspect 19. The apparatus of aspect 18, wherein: the low-frequency control module is configured to apply the low-frequency electromagnetic signal to the qubit coupling circuit such that each energy level associated with the hybridized quantum system acquires an energy shift that is based at least in part on the low-frequency electromagnetic signal; and the high-frequency control module configured to apply the high-frequency electromagnetic signal to drive a transition between a computational state that is in the computational subspace of the hybridized quantum system to a non-computational state within the non-computational subspace of the hybridized quantum system such that the computational state acquires a phase shift based at least in part on the amplitude, the frequency, the envelope shape, and the duration of the high-frequency electromagnetic signal.

Aspect 20. The apparatus of aspect 18, wherein: the low-frequency control module is configured to apply the low-frequency electromagnetic signal to the qubit coupling circuit such that each energy level associated with the hybridized quantum system acquires an energy shift that is based at least in part on the low-frequency electromagnetic signal; and the high-frequency control module is configured to apply the high-frequency electromagnetic signal to drive a transition between a computational state that is in the computational subspace of the hybridized quantum system to a non-computational state in the non-computational subspace of the hybridized quantum system and then back to the computational state such that the computational state acquires a phase shift based at least in part on the amplitude, the frequency, the envelope shape, and the duration of the high-frequency electromagnetic signal.

Aspect 21. The apparatus of aspect 18, wherein the qubit coupling circuit has at least two modes associated with respective energy levels that are based at least in part on a first superconducting phase and a second superconducting phase.

Aspect 22. The apparatus of aspect 21, wherein the qubit coupling circuit is configured to include a coupling suppression state between the first fluxonium qubit circuit and the second fluxonium qubit circuit in which coupling through a first mode of the qubit coupling circuit at least partially cancels coupling through a second mode of the qubit coupling circuit.

Aspect 23. The apparatus of aspect 18, wherein the low-frequency control module is configured to apply a low-frequency electromagnetic signal to each of the fluxonium qubit circuits.

Aspect 24. An apparatus for quantum computing comprising: a first fluxonium qubit circuit configured to have a first energy level; a second fluxonium qubit circuit configured to have a second energy level; a qubit coupling circuit configured to have a third energy level and a fourth energy level, where: the first fluxonium qubit circuit and the second fluxonium qubit circuit are each connected to the qubit coupling circuit such that the first energy level, the second energy level, the third energy level, and the fourth energy level form a hybridized quantum system, and the qubit coupling circuit is configured to include a coupling suppression state between the first fluxonium qubit circuit and the second fluxonium qubit circuit in which coupling through the third energy level at least partially cancels coupling through the fourth energy level; a low-frequency control module configured to apply a low-frequency electromagnetic signal to the qubit coupling circuit; and a high-frequency control module configured to apply a high-frequency electromagnetic signal to at least one of the first fluxonium qubit circuit, the second fluxonium qubit circuit, or the qubit coupling circuit, where a frequency of the high-frequency electromagnetic signal is higher than a frequency of the low-frequency electromagnetic signal.

Aspect 25. The apparatus of aspect 24, wherein the low-frequency control module is configured to apply a low-frequency electromagnetic signal to each of the fluxonium qubit circuits.

Aspect 26. An apparatus for quantum computing comprising: a first qubit circuit; a second qubit circuit; a qubit coupling circuit connected to the first qubit circuit and the second qubit circuit such that energy levels associated with each of the first qubit circuit, the second qubit circuit, and the qubit coupling circuit form a hybridized quantum system comprising a computational subspace and a non-computational subspace; a low-frequency control module configured to apply a low-frequency electromagnetic signal to the qubit coupling circuit such that each energy level in the hybridized quantum system acquires an energy shift that is based at least in part on the low-frequency electromagnetic signal; and a high-frequency control module configured to apply a high-frequency electromagnetic signal having an amplitude, a frequency, an envelope shape, and a duration to drive a transition between a computational state that is in the computational subspace of the hybridized quantum system to a non-computational state in the non-computational subspace of the hybridized quantum system such that the computational state acquires a phase shift based at least in part on the amplitude, the frequency, the envelope shape, and the duration of the high-frequency electromagnetic signal, where the frequency of the high-frequency electromagnetic signal is higher than a frequency of the low-frequency electromagnetic signal.

Aspect 27. The apparatus of aspect 26, wherein the high-frequency control module is configured to apply a high-frequency electromagnetic signal based at least in part on the energy shift of the hybridized quantum system following the application of the low-frequency electromagnetic signal.

Aspect 28. A method for performing quantum operations between a first qubit circuit and a second qubit circuit, the method comprising: providing control signals for controlling a hybridized quantum system comprising a computational subspace and a non-computational subspace associated with energy levels associated with each of: a first qubit circuit, a second qubit circuit, and a qubit coupling circuit, tuning energy levels associated with the hybridized quantum system by applying a low-frequency electromagnetic signal to the hybridized quantum system; preparing a computational state in the computational subspace of the hybridized quantum system; and driving a transition between the computational state and a non-computational state in the non-computational subspace of the hybridized quantum system by applying a high-frequency electromagnetic signal having an amplitude, a frequency, an envelope shape, and a duration to the hybridized quantum system such that the computational state acquires a phase shift based at least in part on the amplitude, the frequency, the envelope shape, and the duration of the high-frequency electromagnetic signal, and where the frequency of the high-frequency electromagnetic signal is higher than a frequency of the low-frequency electromagnetic signal.

Aspect 29. An apparatus comprising: a first qubit circuit; a second qubit circuit; a qubit coupling circuit comprising a first circuit module configured to generate a first superconducting phase and a second circuit module configured to generate a second superconducting phase; a low-frequency control module configured to apply a low-frequency electromagnetic signal to the qubit coupling circuit; and a high-frequency control module configured to apply a high-frequency electromagnetic signal to at least one of the first qubit circuit, the second qubit circuit, or the qubit coupling circuit, where a frequency of the high-frequency electromagnetic signal is higher than a frequency of the low-frequency electromagnetic signal, wherein the first qubit circuit and the second qubit circuit interact with the qubit coupling circuit, and wherein the qubit coupling circuit has two modes associated with respective energy levels that are based at least in part on the first superconducting phase and the second superconducting phase.

Aspect 30. The apparatus of aspect 29, wherein a first energy level associated with a first mode is associated with a sum of the first superconducting phase and the second superconducting phase and a second energy level associated with a second mode is associated with a difference between the first superconducting phase and the second superconducting phase.

Aspect 31. The apparatus of aspect 29, wherein the qubit coupling circuit is configured to include a coupling suppression state between the first qubit circuit and the second qubit circuit in which coupling through one mode at least partially cancels coupling through the other mode.

Aspect 32. An apparatus comprising: an array of coupled qubit circuits in a housing configured to provide a low-temperature environment, the array of coupled qubit circuits comprising: a first qubit circuit, a second qubit circuit, and a first qubit coupling circuit configured to couple the first qubit circuit to the second qubit circuit; a low-frequency control module configured to apply low-frequency electromagnetic signals individually to different respective qubit coupling circuits in the array of coupled qubit circuits; and a high-frequency control module configured to apply a high-frequency electromagnetic signal collectively to each of a plurality of qubit circuits or to each of a plurality of qubit coupling circuits in the array of coupled qubit circuits, where a frequency of the high-frequency electromagnetic signal is higher than all frequencies of the low-frequency electromagnetic signals.

Aspect 33. The apparatus of aspect 32, wherein the high-frequency electromagnetic signal is mixed with the low-frequency electromagnetic signal before the high-frequency electromagnetic signal is applied collectively to each of a plurality of qubit circuits or to each of a plurality of qubit coupling circuits in the array of coupled qubit circuits.

Aspect 34. The apparatus of aspect 32, wherein the high-frequency electromagnetic signal is applied collectively to each of the qubit circuits or to each of the qubit coupling circuits.

Aspect 35. The apparatus of aspect 32, wherein: the array of coupled qubit circuits further comprises: a third qubit circuit, a second qubit coupling circuit configured to couple the first qubit circuit to the third qubit circuit, a fourth qubit circuit, a fifth qubit circuit, and a sixth qubit circuit, a third qubit coupling circuit configured to couple the fourth qubit circuit to the fifth qubit circuit, and a fourth qubit coupling circuit configured to couple the fourth qubit circuit to the sixth qubit circuit; and the plurality of qubit coupling circuits in the array of coupled qubit circuits to which the high-frequency electromagnetic signal is collectively applied includes the first qubit coupling circuit and the third qubit coupling circuit.

Aspect 36. The apparatus of aspect 35, wherein the low-frequency control module and the high-frequency control module are configured to: perform a first 2-qubit gate operation by providing a first low-frequency electromagnetic signal and a first high-frequency electromagnetic signal to the first qubit coupling circuit; and perform a second 2-qubit gate operation by providing a second low-frequency electromagnetic signal and the first high-frequency electromagnetic signal to the third qubit coupling circuit.

Aspect 37. The apparatus of aspect 36, wherein the low-frequency control module is configured to: provide a third low-frequency electromagnetic signal that suppresses coupling by the second qubit coupling circuit concurrently with the first 2-qubit gate operation; and provide a fourth low-frequency electromagnetic signal that suppresses coupling by the fourth qubit circuit concurrently with the second 2-qubit gate operation.

Aspect 38. The apparatus of aspect 37, wherein the third low-frequency electromagnetic signal suppresses coupling by the second qubit coupling circuit based at least in part on a first mode associated with a first circuit portion and a second mode associated with a second circuit portion, where a coupling associated with the first mode at least partially cancels a coupling associated with the second mode.

Aspect 39. The apparatus of aspect 35, wherein the low-frequency electromagnetic signals are applied based at least in part on digital control signals received from a digital signal interface providing the digital control signals into the housing.

Aspect 40. The apparatus of aspect 39, wherein the digital signal interface comprises one or more adiabatic quantum flux parametrons.

Aspect 41. The apparatus of aspect 35, wherein the low-frequency electromagnetic signals are applied individually to different respective qubit coupling circuits based at least in part on calibration information corresponding to the different respective qubit coupling circuits.

Aspect 42. The apparatus of aspect 32, wherein the first qubit circuit comprises a fluxonium qubit circuit, the second qubit circuit comprises a fluxonium qubit circuit, and the first qubit coupling circuit comprises: a first circuit portion including one or more Josephson junctions, and a second circuit portion including one or more Josephson junctions.

Aspect 43. The apparatus of aspect 42, wherein the first circuit portion includes two or more Josephson junctions connected in series over a first closed path without any capacitors in the first closed path.

Aspect 44. The apparatus of aspect 43, wherein the second circuit portion includes two or more Josephson junctions connected in series over a second closed path without any capacitors in the second closed path, the first circuit portion includes a first capacitor that connects a first portion of the first closed path and a second portion of the first closed path, and the second circuit portion includes a second capacitor that connects a first portion of the second closed path and a second portion of the second closed path.

Aspect 45. The apparatus of aspect 42, wherein the second circuit portion includes two or more Josephson junctions connected in series over a second closed path without any capacitors in the second closed path.

Aspect 46. The apparatus of aspect 42, wherein the first circuit portion is coupled to the first qubit circuit through a first node and is coupled to the second qubit circuit through a second node different from the first node, and the second circuit portion is coupled to the first qubit circuit through a third node and is coupled to the second qubit circuit through the third node.

Aspect 47. The apparatus of aspect 32, wherein the first qubit circuit comprises a fluxonium qubit circuit, the second qubit circuit comprises a fluxonium qubit circuit, and the first qubit coupling circuit comprises: a first non-ground node which is capacitively coupled to the first fluxonium qubit; a second non-ground node, which is different from the first non-ground node and capacitively coupled to the second fluxonium qubit; and one or more Josephson junctions connected in series over a path between the first non-ground node and the second non-ground node.

Aspect 48. The apparatus of aspect 32, further comprising a first integrated circuit chip on which a first plurality of qubit circuits in the array of coupled qubit circuits are arranged.

Aspect 49. The apparatus of aspect 48, further comprising a second integrated circuit chip on which a second plurality of qubits circuits in the array of coupled qubit circuits are arranged.

Aspect 50. The apparatus of aspect 49, further comprising a third integrated circuit chip on which a plurality of qubit coupling circuits in the array of coupled qubit circuits are arranged.

Aspect 51. An apparatus comprising: an array of coupled qubit circuits in a housing configured to provide a low-temperature environment, the array of coupled qubit circuits comprising: a first qubit circuit, a second qubit circuit, and a first qubit coupling circuit configured to couple the first qubit circuit to the second qubit circuit; a plurality of frequency mixers coupled to a plurality of qubit circuits or a plurality of qubit coupling circuits in the array of coupled qubit circuits; a low-frequency control module configured to apply low-frequency electromagnetic signals individually to different respective qubit coupling circuits in the array of coupled qubit circuits and to different respective frequency mixers in the plurality of frequency mixers; and a high-frequency control module configured to apply a high-frequency electromagnetic signal collectively to the plurality of frequency mixers, where a frequency of the high-frequency electromagnetic signal is higher than all frequencies of the low-frequency electromagnetic signals; wherein each frequency mixer in the plurality of frequency mixers is configured to apply an electromagnetic signal to the plurality of qubit circuits or the plurality of qubit coupling circuits in the array of coupled qubit circuits, where a frequency of the applied electromagnetic signal is a sum of or difference between a frequency of the high-frequency electromagnetic signal and a frequency of one of the low-frequency electromagnetic signals.

Aspect 52. The apparatus of aspect 51, wherein the low-frequency electromagnetic signals are applied to different respective qubit coupling circuits in the array of coupled qubit circuits and the frequency mixers apply an electromagnetic signal to the plurality of qubit coupling circuits in the array of coupled qubit circuits, where a frequency of the applied electromagnetic signal is a sum of or difference between a frequency of the high-frequency electromagnetic signal and a frequency of one of the low-frequency electromagnetic signals.

Aspect 53. The system of aspect 1, wherein the coupling circuit comprises a first sub-circuit that is: connected to a ground on a first side of the first sub-circuit via one or more first capacitively shunted inductive elements; connected on the first side to the first fluxonium qubit via a first capacitor; connected to the ground on a second side of the first sub-circuit via one or more second capacitively shunted inductive elements; and connected on the second side to the second fluxonium qubit via a second capacitor.

Aspect 54. The system of aspect 53, wherein: the one or more first capacitively shunted inductive elements comprise one or more first Josephson junctions connected to the ground in parallel with a third capacitor; and the one or more second capacitively shunted inductive elements comprise one or more second Josephson junctions connected to the ground in parallel with a fourth capacitor.

Aspect 55. The system of aspect 53, wherein the first sub-circuit comprises one or more Josephson junctions connecting the first side of the first sub-circuit to the second side of the first sub-circuit.

Such alterations, modifications, and improvements are intended to be part of this disclosure and are intended to be within the spirit and scope of the disclosure. Further, though advantages of the present disclosure are indicated, it should be appreciated that not every embodiment of the technology described herein will include every described advantage. Some embodiments may not implement any features described as advantageous herein and in some instances one or more of the described features may be implemented to achieve further embodiments. Accordingly, the foregoing description and drawings are by way of example only.

Aspects of the above-described embodiments of the technology described herein can be implemented in any of numerous ways. For example, aspects of the embodiments may be implemented using hardware, software, or a combination thereof. When implemented in software, the software code can be executed on any suitable processor or collection of processors, whether provided in a single computer or distributed among multiple computers. Such processors may be implemented as integrated circuits, with one or more processors in an integrated circuit component, including commercially available integrated circuit components known in the art by names such as CPU chips, GPU chips, microprocessor, microcontroller, or co-processor. Alternatively, a processor may be implemented in custom circuitry, such as an ASIC, or semi-custom circuitry resulting from configuring a programmable logic device. As yet a further alternative, a processor may be a portion of a larger circuit or semiconductor device, whether commercially available, semi-custom or custom. As a specific example, some commercially available microprocessors have multiple cores such that one or a subset of those cores may constitute a processor. Though, a processor may be implemented using circuitry in any suitable format.

Various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, aspects of the disclosure may be embodied as a method, of which examples have been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. A system comprising:
a first fluxonium qubit;
a second fluxonium qubit;
a coupling circuit coupled to each of the first fluxonium qubit and the second fluxonium qubit, the coupling circuit exhibiting at least two modes; and
at least one controller configured to adjust one or more energy levels of the at least two modes of the coupling circuit to thereby increase or decrease a coupling strength between the first fluxonium qubit and the second fluxonium qubit via one or more of the at least two modes of the coupling circuit.

2. The system of claim 1, wherein the at least one controller is configured to adjust the one or more energy levels of the at least two modes of the coupling circuit by controlling a magnetic flux bias threaded through a superconducting loop of the coupling circuit.

3. The system of claim 1, wherein the coupling circuit is capacitively coupled to the first fluxonium qubit, and is, independent of the capacitive coupling to the first fluxonium qubit, capacitively coupled to the second fluxonium qubit.

4. The system of claim 1, wherein the coupling circuit comprises a first superconducting sub-circuit, and a second superconducting sub-circuit connected in parallel with the first superconducting sub-circuit.

5. The system of claim 4, wherein the first superconducting sub-circuit comprises a plurality of Josephson junctions connected in parallel with at least one capacitor.

6. The system of claim 4, wherein the second superconducting sub-circuit comprises a plurality of Josephson junctions connected in parallel with at least one capacitor.

7. The system of claim 4, wherein the second superconducting sub-circuit comprises a linear inductor connected in parallel with at least one capacitor.

8. The system of claim 4, wherein the first fluxonium qubit is capacitively coupled to each of the first superconducting sub-circuit and the second superconducting sub-circuit in parallel, and wherein the second fluxonium qubit is capacitively coupled to each of the first superconducting sub-circuit and the second superconducting sub-circuit in parallel.

9. The system of claim 1, wherein the coupling circuit is coupled to ground.

10. The system of claim 1, wherein the coupling circuit comprises one or more Josephson junctions connected in parallel to at least one capacitor.

11. The system of claim 10, wherein the one or more Josephson junctions are connected to the first fluxonium qubit via a first capacitor, and wherein the one or more Josephson junctions are connected to the second fluxonium qubit via a second capacitor.

12. The system of claim 1, wherein the coupling circuit comprises a first sub-circuit that is:
connected to a ground on a first side of the first sub-circuit via one or more first capacitively shunted inductive elements;
connected on the first side to the first fluxonium qubit via a first capacitor;
connected to the ground on a second side of the first sub-circuit via one or more second capacitively shunted inductive elements; and
connected on the second side to the second fluxonium qubit via a second capacitor.

13. The system of claim 12, wherein:
the one or more first capacitively shunted inductive elements comprise one or more first Josephson junctions connected to the ground in parallel with a third capacitor; and
the one or more second capacitively shunted inductive elements comprise one or more second Josephson junctions connected to the ground in parallel with a fourth capacitor.

14. The system of claim 12, wherein the first sub-circuit comprises one or more Josephson junctions connecting the first side of the first sub-circuit to the second side of the first sub-circuit.

15. The system of claim 1, wherein the at least one controller is configured to perform an entangling gate between the first fluxonium qubit and the second fluxonium qubit by applying at least one microwave pulse to at least one of the first fluxonium qubit, the second fluxonium qubit and the coupling circuit.

16. The system of claim 1, wherein the at least one controller is configured to adjust the one or more energy levels of the at least two modes of the coupling circuit to reduce the coupling strength between the first fluxonium qubit and the second fluxonium qubit to zero.

17. The system of claim 1, wherein the coupling circuit is a superconducting circuit.

18. A method comprising:
controlling a flux bias of a coupling circuit, wherein the coupling circuit is coupled to a first fluxonium qubit and a second fluxonium qubit and exhibits at least two modes, wherein controlling the flux bias of the coupling circuit increases a coupling strength between the first fluxonium qubit and the second fluxonium qubit via one or more of the at least two modes of the coupling circuit; and
applying at least one microwave pulse to at least one of the first fluxonium qubit, the second fluxonium qubit and the coupling circuit to perform an entangling gate between the first fluxonium qubit and the second fluxonium qubit.

19. The method of claim 18, wherein controlling the flux bias of the coupling circuit comprises controlling a magnetic flux bias threaded through a superconducting loop of the coupling circuit.

20. The method of claim 18, wherein controlling the flux bias of the coupling circuit hybridizes at least one energy level of the at least two modes of the coupling circuit with an energy level of the first fluxonium qubit and an energy level of the second fluxonium qubit.
